(19) United States
(12) Patent Application Publication
(10) Pub. No.: US 2024/0128294 A1
(43) Pub. Date: Apr. 18, 2024

(54) IMAGE READING DEVICE

(71) Applicant: Mitsubishi Electric Corporation, Tokyo (JP)

(72) Inventors: Hiroyuki KAWANO, Tokyo (JP); Naoki NAKAGAWA, Tokyo (JP); Takeshi ONO, Tokyo (JP); Shigeru TAKUSHIMA, Tokyo (JP); Naoyuki TOKIDA, Tokyo (JP); Akira OTA, Tokyo (JP); Miki SUGANO, Tokyo (JP)

(73) Assignee: Mitsubishi Electric Corporation, Tokyo (JP)

(21) Appl. No.: 18/276,454

(22) PCT Filed: Feb. 25, 2021
(86) PCT No.: PCT/JP2021/007003

§ 371 Date: Aug. 9, 2023

(51) Int. Cl. H01L 27/146; H04N 1/03

(52) U.S. Cl. CPC H01L 27/14627; H04N 1/0306

(57) ABSTRACT

An image reading device includes a plurality of light receiving parts arrayed regularly, a first light blocking member including a plurality of first openings arrayed corresponding respectively to the plurality of light receiving parts, and a plurality of microlenses arrayed corresponding respectively to the plurality of first openings. Each light receiving part included in the plurality of light receiving parts includes a plurality of light receiving pixels arrayed in a first direction as a main scanning direction. Each microlens included in the plurality of microlenses is object side telecentric. The plurality of microlenses, the first light blocking member and the plurality of light receiving parts are arranged so that light reflected by an object and passing through the microlens and the first opening corresponding to the microlens enters the plurality of light receiving pixels included in the light receiving part corresponding to the first opening.

### TECHNICAL FIELD

The present disclosure relates to an image reading device.

### BACKGROUND ART

There has been known an image reading device that acquires two-dimensional image information by optically reading an object as an image capture target (hereinafter referred to also as a “subject”). See Patent Reference 1, for example.

The image reading device of the Patent Reference 1 includes a plurality of light receiving parts arrayed regularly, a light blocking member having a plurality of openings arrayed corresponding respectively to the plurality of light receiving parts, and a plurality of microlenses arrayed corresponding respectively to the plurality of openings.

In the Patent Reference 1, each light receiving part includes a plurality of light receiving pixels arrayed in an X-axis direction and a Y-axis direction on an XY plane. With this configuration, the resolution increases. In the Patent Reference 1, an imaging optical system is formed by one light receiving pixel, an opening corresponding to the light receiving pixel, and a microlens corresponding to the opening.

### PRIOR ART REFERENCE

### Patent Reference

Patent Reference 1: Japanese Patent Application Publication No. 2009-524263

### SUMMARY OF THE INVENTION

### Problem to be Solved by the Invention

However, in the image reading device of the Patent Reference 1, the optical axis of each microlens is inclined with respect to a direction orthogonal to the XY plane. Thus, there is a problem in that an overlap of visual fields between adjoining imaging optical systems changes and precision of image processing deteriorates when the distance between the light receiving part and the subject changes. In this case, the depth of field decreases. A technology that increases the depth of field while improving the resolution is being requested.

An object of the present disclosure is to increase the depth of field while improving the resolution.

### Means for Solving the Problem

An image reading device according to an aspect of the present disclosure is an image reading device that optically reads an object as an image capture target, including a plurality of light receiving parts arrayed regularly, a first light blocking member including a plurality of first openings arrayed corresponding respectively to the plurality of light receiving parts, and a plurality of microlenses arrayed corresponding respectively to the plurality of first openings. Each light receiving part included in the plurality of light receiving parts includes a plurality of light receiving pixels arrayed in a first direction as a main scanning direction. Each microlens included in the plurality of microlenses is object side telecentric. The plurality of microlenses, the first light blocking member and the plurality of light receiving parts are arranged so that light reflected by the object and passing through toe microlens and the first opening corresponding to the microlens enters the plurality of light receiving pixels included in the light receiving part corresponding to the first opening.

### Effect of the Invention

According to the present disclosure, the depth of field can be increased while improving the resolution.

### BRIEF DESCRIPTION OF THE DRAWINGS

FIG. 1 is a perspective view schematically showing a main configuration of an image reading device according to a first embodiment.

FIG. 2 is a cross-sectional view of the image reading device shown in FIG. 1 taken along the line A2-A2.

FIG. 3 is a cross-sectional view of the image reading device shown in FIG. 1 taken along the line A3-A3.

FIG. 4 is a plan view showing a part of a configuration of an imaging element unit shown in FIGS. 1 to 3.

FIG. 5A is a plan view showing a configuration of a light receiving pixel unit arranged at a position closest to a +X-axis direction end of a sensor chip among a plurality of light receiving pixel units shown in FIG. 4.

FIG. 5E is a plan view showing a configuration of a light receiving pixel unit arranged at a position closest to a −X-axis direction end of the sensor chip among the plurality of light receiving pixel units shown in FIG. 4.

FIG. 5C is a plan view showing the configuration of a light receiving pixel unit among the plurality of light receiving pixel units shown in FIG. 4 other than the light receiving pixel units shown in FIGS. 5A and 5B.

FIG. 6 is a diagram schematically showing a configuration of an illuminating optical unit shown in FIG. 1 and illuminating light emitted from the illuminating optical unit.

FIG. 7A is a plan view showing two light receiving pixel units situated in the same line.

FIG. 7B is a diagram showing image forming rays in reflected light entering each of the two light receiving pixel units shown in FIG. 7A.

FIG. 8 is a diagram showing a part of the configuration of the image reading device shown in FIG. 3 and principal rays in the image reading device.

FIG. 9 is a diagram showing principal rays entering a light receiving pixel unit situated in a first line and principal rays entering a light receiving pixel unit situated in a second line in the image reading device according to the first embodiment.

FIG. 10 is a diagram showing a part of the configuration of the image reading device shown in FIG. 3 and the reflected light passing through a first opening and a second opening.

FIGS. 11A and 11B are diagrams for explaining conditions for the reflected light after passing through the second opening and the first opening corresponding to a light receiving pixel to enter the light receiving pixel in the image reading device according to the first embodiment.

FIG. 12 is a cross-sectional view of the image reading device shown in FIG. 1 taken along the line A12-A12.

FIG. 13 is a diagram showing inverse rays heading in a +Z-axis direction from a light receiving pixel unit in the image reading device according to the first embodiment.

FIG. 14 is a diagram showing an inclination of an optical axis of a microlens when displacement of a first glass member and a second glass member occurs in the image reading device according to the first embodiment.

FIG. 15 is a diagram showing X-axis direction positions of visual fields of the microlenses when variation an mounting of sensor chips occurs in an image reading device according to a comparative example.

FIG. 16 is a cross-sectional view schematically showing a main configuration of an image reading device according to a second embodiment.

FIG. 17 is a cross-sectional view schematically showing a main configuration of an image reading device according to a modification of the second embodiment.

FIG. 18 is a plan view showing a configuration of an imaging element unit of an image reading device according to a third embodiment.

FIG. 19 is a plan view showing a configuration of an imaging element unit of an image reading device according to a fourth embodiment.

FIG. 20 is a cross-sectional view schematically showing a main configuration of an image reading device according to a fifth embodiment.

FIG. 21 is a cross-sectional view schematically showing a main configuration of an image reading device according to a first modification of the fifth embodiment.

FIG. 22 is a cross-sectional view schematically showing a main configuration of an image reading device according to a second modification of the fifth embodiment.

FIG. 23 is a cross-sectional view schematically showing a main configuration of an image reading device according to a sixth embodiment.

### MODE FOR CARRYING OUT THE INVENTION

Image reading devices according to embodiments of the present disclosure will be described below with reference to the drawings. The following embodiments are just examples and a variety of modifications are possible within the scope of the present disclosure.

### Configuration of Image Reading Device

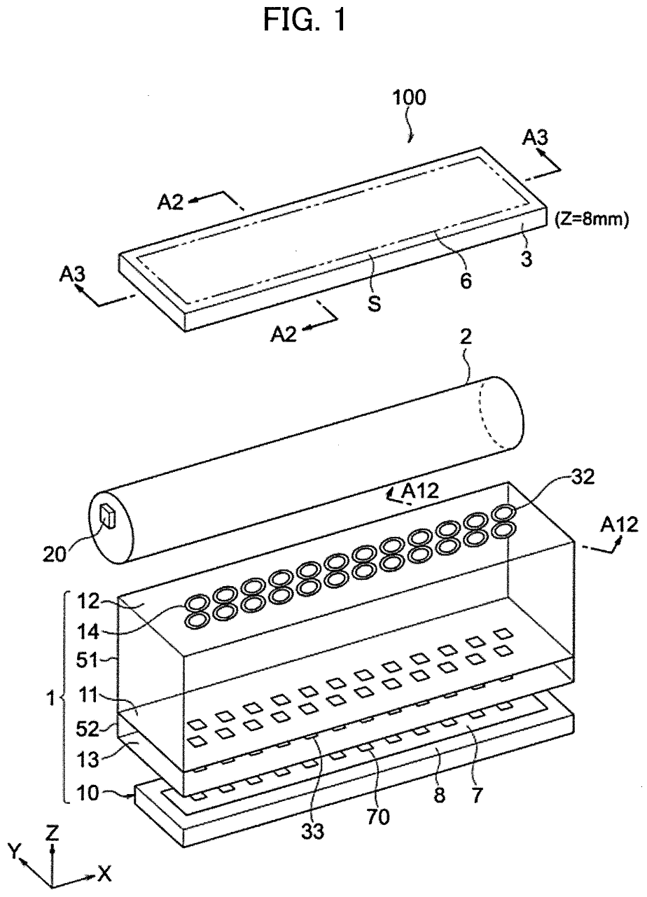

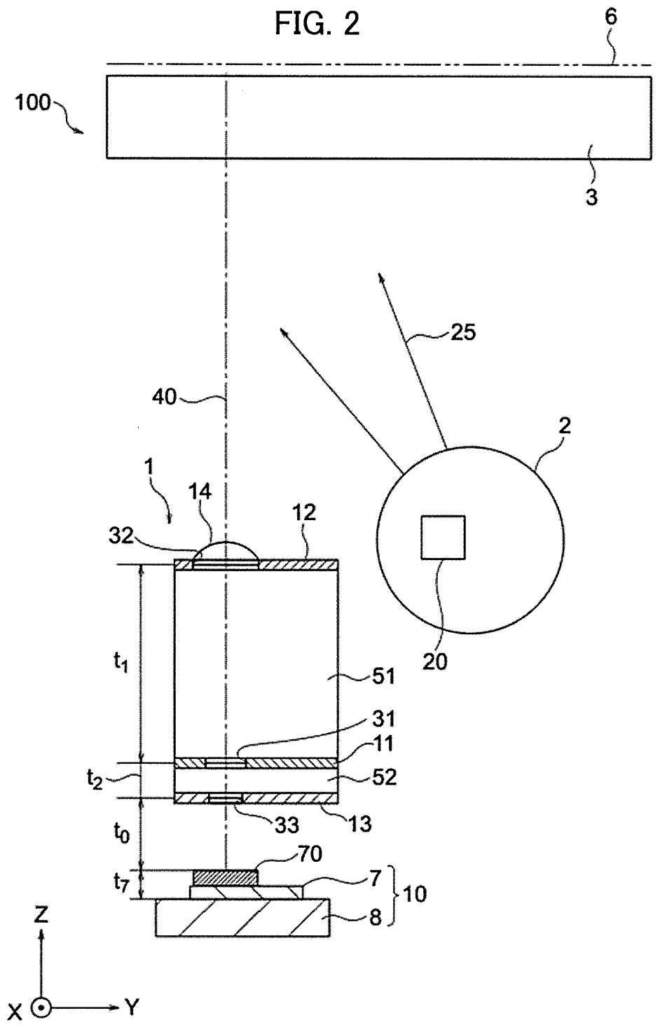

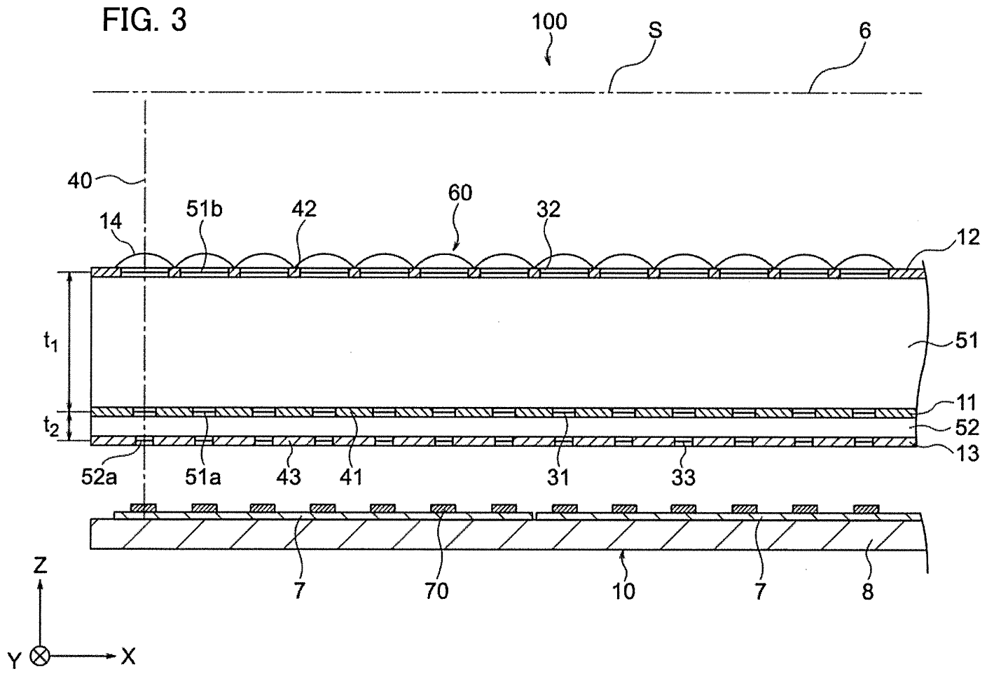

FIG. 1 is a perspective view schematically showing a main configuration of an image reading device 100 according to a first embodiment. FIG. 2 is a cross-sectional view of the image reading device 100 shown in FIG. 1 taken along the line A2-A2. FIG. 3 is a cross-sectional view of the image reading device 100 shown in FIG. 1 taken along the line A3-A3. As shown in FIGS. 1 to 3, the image reading device 100 includes an imaging optical unit 1, an illuminating optical unit 2, and a glass top plate 3 as a document setting table. When illuminating light 25 from the illuminating optical unit 2 is applied to a document 6 arranged on the glass top plate 3, the illuminating light 25 is scattered and reflected by the document 6. The scattered and reflected light (hereinafter referred to also as “reflected light”) is received by the imaging optical unit 1, by which image information on the document 6 is read out. As above, the image reading device 100 is an image reading device that optically reads the document 6.

In the first embodiment, in order for the imaging optical unit 1 to acquire two-dimensional image information on the document 6, the document 6 is conveyed by a conveyance unit (not shown) along the glass top plate 3 in an auxiliary scanning direction as a second direction orthogonal to a main scanning direction as a first direction. This operation makes it possible to scan the whole of the document 6. In the first embodiment, the main scanning direction is an X-axis direction, and the auxiliary scanning direction is a Y-axis direction. It is also possible to execute the scan of the whole of the document 6 by moving the imaging optical unit 1 in the Y-axis while leaving the document 6 still.

The document 6 is an example of an image capture target that undergoes image capturing by the imaging optical unit 1. The document 6 is, for example, a print that has been printed with characters, an image or the like. The document 6 is arranged on a predetermined reference surface S. The reference surface S is a plane on which the document 6 is set, specifically, a surface on the glass top plate 3. The glass top plate 3 is situated between the document 6 and the imaging optical unit 1. The thickness of the glass top plate 3 is 1.0 mm, for example. The structure for setting the document 6 on the reference surface S is not limited to the glass top plate 3.

### Configuration of Imaging Optical Unit

The imaging optical unit 1 includes an imaging element unit 10 as an imaging section, a first light blocking member 11 having a plurality of openings 31, a second light blocking member 12 having a plurality of openings 32, a third light blocking member 13 having a plurality of openings 33, and a plurality of microlenses 14.

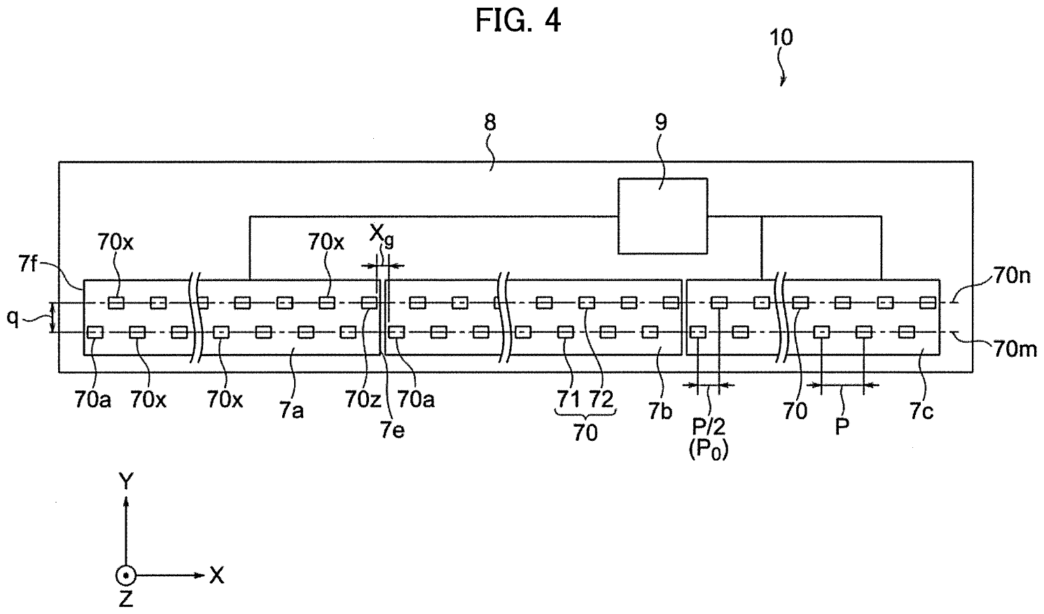

FIG. 4 is a plan view showing a part of the configuration of the imaging element unit 10 shown in FIGS. 1 to 3. As shown in FIGS. 1 to 4, the imaging element unit 10 includes a plurality of sensor chips 7a, 7b, 7c, a sensor substrate 8, and an image processing device 9. The plurality of sensor chips 7a, 7b, 7c are arrayed in the X-axis direction. When it is unnecessary to distinguish between the sensor chips 7a, 7b, 7c in the following description, the sensor chips 7a, 7b, 7c will be collectively referred to as “sensor chips 7”.

The sensor chips 7 are formed from silicon material, for example. The sensor chips 7 are provided on the sensor substrate 8. The sensor chips 7 are electrically connected to the sensor substrate 8 by means of wire bonding, for example. The sensor substrate 8 is a mounting substrate, and is formed from glass epoxy resin, for example.

The image processing device 9 executes image processing based on an image signal outputted from the sensor chips 7. The image processing device 9 is, for example, an ASIC (Application Specific Integrated Circuit) mounted on the sensor substrate 8. The image processing device 9 can also be implemented by an arithmetic processing device not mounted on the sensor substrate 8. Details of the image processing executed by the image processing device 9 will be described later.

On each sensor chip 7, a plurality of light receiving pixel units 70 as a plurality of light receiving parts regularly arrayed are arranged. The plurality of light receiving pixel units 70 are arrayed in the X-axis direction. Each sensor chip 7 includes 64 light receiving pixel units 70, for example. Each light receiving pixel unit 70 receives reflected light reflected by the document 6. Each sensor chip 7 is not limited to the configuration described in the first embodiment but can be implemented by a set of an arbitrary number of light receiving pixel units 70.

As shown in FIG. 4, the plurality of light receiving pixel units 70 include a plurality of light receiving pixel units 71 in a first line 70m and a plurality of light receiving pixel units 72 in a second line 70n arrayed at different positions in the Y-axis direction. An interval P between central positions of two light receiving pixel units 71 (or two light receiving pixel units 72) adjoining in the X-axis direction (hereinafter referred to as a “pitch”) is 320 μm, for example. An interval q between the central positions of the light receiving pixel unit 71 and the light receiving pixel unit 72 adjoining in the Y-axis direction is 400 μm, for example.

In the first embodiment, each light receiving pixel unit 72 in the second line 70n is situated in the middle of two light receiving pixel units 71 in the first line 70m. Specifically, the light receiving pixel units 72 are arranged to deviate in the X-axis direction relative to the light receiving pixel units 71 belonging to a different line by a distance P/2 (hereinafter referred to also as a “pitch P₀”) as ½ of the pitch P. By this arrangement, in the first embodiment, the plurality of light receiving pixel units 70 are arrayed in a zigzag pattern. Therefore, in the first embodiment, the pitch P can be increased compared to a configuration in which a plurality of light receiving pixel units are arrayed in one line, and thus the image reading device 100 is capable of acquiring an image not affected by stray light. Further, since the openings can be enlarged, luminance of the image increases.

The plurality of light receiving pixel units 70 included in one sensor chip 7 include light receiving pixel units 70z and 70a as first light receiving parts and light receiving pixel units 70x as second light receiving parts being light receiving parts other than the light receiving pixel units 70z and 70a. The light receiving pixel unit 70z is a light receiving pixel unit arranged at a positron closest to a +X-axis direction end 7e of the sensor chip 7. The light receiving pixel unit 70a is a light receiving pixel unit arranged at a position closest no a −X-axis direction end 71 of the sensor chip 7.

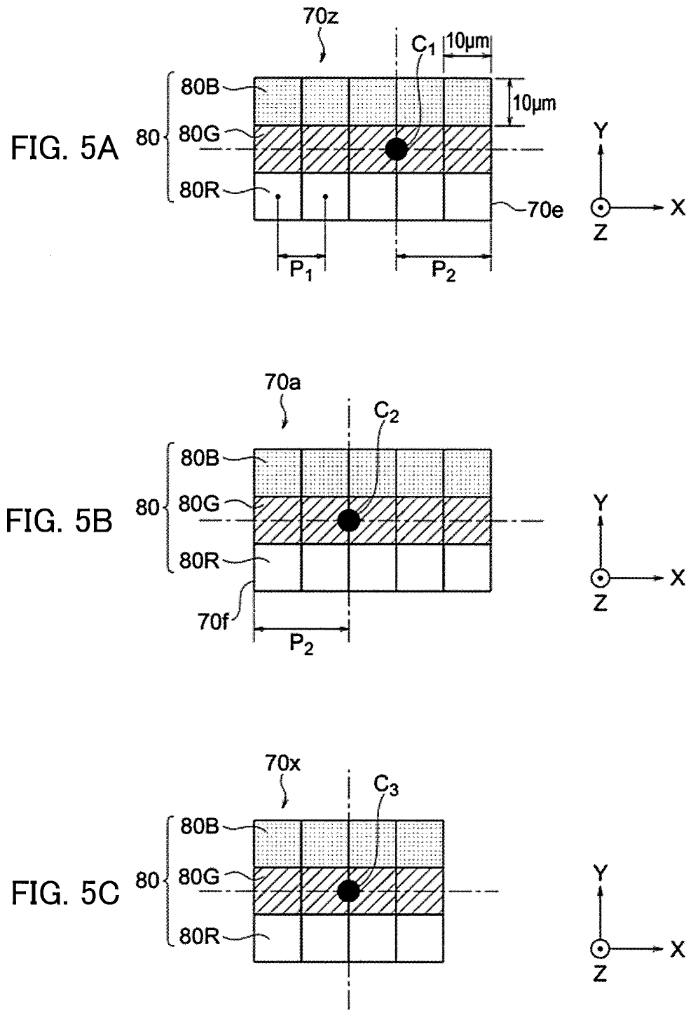

FIG. 5A is a plan view showing the configuration of the light receiving pixel unit 70z. FIG. 5B is a plan view showing the configuration of the light receiving pixel unit 70a. As shown in FIGS. 5A and 5B, each of the light receiving pixel units 70z and 70a includes a plurality of light receiving pixels 80. Specifically, in each light receiving pixel unit 70z, 70a, five light receiving pixels 80 are arrayed in the X-axis direction and three light receiving pixels 80 are arrayed in the Y-axis direction. In the first embodiment, each light receiving pixel 80 is in a square shape of 10 μm×10 μm, for example. Therefore, each light receiving pixel unit 70z, 70a is in a rectangular shape of 50 μm×30 μm, for example. Further, an interval P₁ between X-axis direction central positions of light receiving pixels 80 adjoining in the X-axis direction is 10 μm.

FIG. 5C is a plan view showing the configuration of the light receiving pixel unit 70x. As shown in FIG. 5C, in the light receiving pixel units 70x, four light receiving pixels 80 are arrayed in the X-axis direction and three light receiving pixels 80 are arrayed in the Y-axis direction. Therefore, each light receiving pixel unit 70x is in a rectangular shape of 40 μm×30 μm, for example. The number of light receiving pixels 80 included in each light receiving pixel unit 70z, 70a, 70x is not limited to the configuration shown in FIGS. 5A to SC. Further, the method of arraying the light receiving pixels 80 in each light receiving pixel unit 70z, 70a, 70x is not limited to the matrix-like pattern; a different arraying method may also be employed.

As above, in the first embodiment, the number of light receiving pixels 80 included in the light receiving pixel unit 70z, 70a is greater than the number of light receiving pixels 80 included in the light receiving pixel unit 70x. Effect of this feature will be described later. The number of light receiving pixels 80 included in the light receiving pixel unit 70z, 70a may also be the same as the number of light receiving pixels 80 included in the light receiving pixel unit 70x. Namely, it is permissible if the number of the plurality of light receiving pixels 80 included in the light receiving pixel unit 70z, 70a is greater than or equal to the number of the plurality of light receiving pixels 80 included in the light receiving pixel unit 70b.

Further, each point C₁, C₂, C₃ respectively shown in FIGS. 5A to 5C represents an intersection point between an optical axis 40 (see FIG. 2, for example) of the microlens 14 and each light receiving pixel unit 70z, 70a, 70x. The point C₃ shown in FIG. 5C coincides with the central position of the light receiving pixel unit 70x.

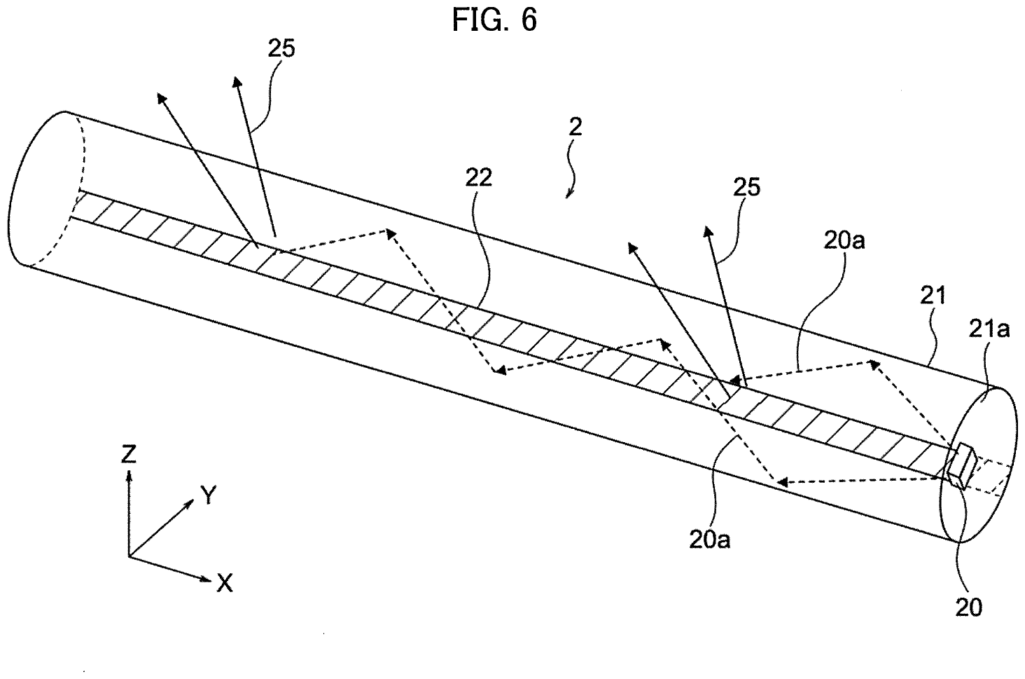

Each light receiving pixel 80 included in the plurality of light receiving pixels 80 includes a color filter (not shown). Specifically, the light receiving pixel unit 70 includes first light receiving pixels 80R each including a red color filter that allows light of red color to pass through, second light receiving pixels 80G each including a green color filter that allows light of green color to pass through, and third light receiving pixels 80B each including a blue color filter that allows light of blue color to pass through. With this configuration, when the illuminating light (e.g., the illuminating light 25 shown in FIG. 6 which will be explained later) is white light, the imaging element unit 10 is capable of acquiring a color image expressed by three colors: red color, blue color and green color. The light receiving pixel unit 70 can be implemented even if the light receiving pixel unit 70 is formed with a plurality of light receiving pixels 80 each including no color filter.

Next, the rest of the configuration of the imaging optical unit 1 will be described below. As shown in FIGS. 1 to 3, the first light blocking member 11 is arranged on the document 6's side relative to the light receiving pixel units 70. The first light blocking member 11 includes the plurality of openings 31 as a plurality or first openings.

The plurality of openings 31 are arranged at positions corresponding respectively to the plurality of light receiving pixel units 70. As viewed in the Z-axis direction, the plurality of openings 31 respectively overlap with the plurality of light receiving pixel units 70. Specifically, on an XY plane, the central position at each opening 31 included in the plurality of openings 31 is the same as the central position of a light receiving pixel unit 70.

The plurality of openings 31 are arrayed in two lines. The openings 31 in each line are arrayed in the X-axis direction. In the first embodiment, the plurality of openings 31 are arrayed in a zigzag pattern. Each opening 31 is in a square shape of 40 μm×40 μm, for example. Reflected light reflected by the document 6 passes through the openings 31. In the first light blocking member 11, a part excluding the openings 31 is a first light blocking part 41 that blocks the reflected light.

The second light blocking member 12 is arranged on the document 6's side relative to the first light blocking member 11. The second light blocking member 12 is arranged between the first light blocking member 11 and the plurality of microlenses 14. The second light blocking member 12 includes the plurality of openings 32 as a plurality of second openings.

The plurality of openings 32 are arranged at positions corresponding respectively to the plurality of microlenses 14. Specifically, on an XY plane, the central position of each opening 32 included in the plurality of openings 32 is the same as the central position of a microlens 14. As viewed in the Z-axis direction, the plurality of openings 32 respectively overlap with the plurality of light receiving pixel units 70.

The plurality of openings 32 are arrayed in two lines. The openings 32 in each line are arrayed in the X-axis direction. Then, the plurality of openings 32 are arrayed in a zigzag pattern. Further, the plurality of openings 32 respectively overlap with the plurality of openings 31, and respectively overlap with the plurality of openings 33 which will be described later.

The opening 32 is in a circular shape, for example. The opening area of the opening 32 is larger than the opening area of the opening 31 and the opening area of the opening 33. Namely, the diameter of the opening 32 (diameter Φ shown in FIG. 13 which will be explained later) is greater than each side of the opening 31, 33. The diameter of the opening 32 is 280 μm, for example. Reflected light reflected by the document 6 passes through the openings 32. In the second light blocking member 12, a part excluding the openings 32 is a second light blocking part 42 that blocks the reflected light.

The imaging optical unit 1 further includes a glass member 51 as a first light-permeable member arranged between the first light blocking member 11 and the second light blocking member 12. The first light blocking member 11 is formed on a surface 51a of the glass member 51 on the −Z-axis side (i.e., the light receiving pixel units 70's side), while the second light blocking member 12 is formed on a surface 51b of the glass member 51 on the +Z-axis side (i.e., tire document 6's side).

The first light blocking member 11 and the second fight blocking member 12 are light blocking layers as thin films formed by chrome oxide films vapor-deposited on the glass member 51. The openings 31 and 32 are formed by etching the chrome oxide films by using mask patterns. By this, positional accuracy and shape accuracy of the openings 31 and 32 can be made excellent. For example, a Y-axis direction position error among the plurality of openings 31 (or among the plurality of openings 32) is approximately 1 μm.

The third light blocking member 13 is arranged on the light receiving pixel units 70's side relative to the first light blocking member 11. The third light blocking member 13 has the plurality of openings 33 as a plurality of third openings. The plurality of openings 33 are arranged at positions corresponding respectively to the plurality of light receiving pixel units 70. As viewed in the Z-axis direction, the plurality of openings 33 respectively overlap with the plurality of light receiving pixel units 70. Specifically, on an XY plane, the central position of each opening 33 in in the plurality of openings 33 is the same as the central position of a light receiving pixel unit 70.

The plurality of openings 33 are arrayed in two lines. The openings 33 in each line are arrayed in the X-axis direction. In the first embodiment, the plurality of openings 33 are arrayed in a zigzag pattern. Each opening 33 is in a square shape of 60 μm×60 μm, for example. Reflected light reflected by the document 6 passes through the openings 33. In the third light blocking member 13, a part excluding the openings 33 is a third light blocking member 13 that blocks the reflected light.

The imaging optical unit 1 further includes a glass member 52 as a second light-permeable member arranged between the first light blocking member 11 and the third light blocking member 13. In other words, the glass member 52 is arranged on the light receiving pixel units 70's side relative to the glass member 51. The third light blocking member 13 is formed on a surface 52a of the glass member 52 on the −Z-axis side (i.e., the light receiving pixel units 70's side). The method of forming the openings 33 is similar to the aforementioned formation method of the openings 31 and 32; the openings 33 are formed by etching a chrome oxide film vapor-deposited on the glass member 52, for example. As shown in FIG. 16 which will be explained later, the imaging optical unit 1 can be implemented even if the imaging optical unit 1 does not include the second light blocking member 12, the third light blocking member 13 and the glass member 52.

As shown in FIG. 3, the glass member 52 is fixed to the glass member 51 by means of bonding by using an adhesive agent or the like so that the central positions of the openings 33 overlap with the central positions of the openings 31 and the central positions of the openings 32. To increase the accuracy of the alignment when bonding the glass member 52 to the glass member 51, a surface of the glass member 52 on the +Z-axis side and the surface 51b of the glass member 51 on the −Z-axis side may be provided with alignment marks (not shown) for the alignment.

The glass members 51 and 52 are members capable of allowing light to pass through, such as glass substrates, for example. In she first embodiment, the refractive index of the glass member 51 is equal to the refractive index of the glass member 52. The refractive indices n of the glass members 51 and 52 are 1.52, for example. The thickness t₁ (see FIG. 2) of the glass member 51 is t₁=2400 μm, for example. The thickness t₂ (see FIG. 2) of the glass member 52 is t₂=300 μm, for example. The refractive index of she glass member 51 may also differ from the refractive index of the glass member 52.

Here, in the case where the aforementioned wire bonding is employed as the method of electrically connecting the sensor chips 7 to the sensor substrate 8, wires can stick out from a +Z-axis side surface of the sensor chip 7 in the +Z-axis direction by approximately 100 to 200 μm. In the first embodiment, spacing t₀ (see FIG. 2) between the light receiving pixel unit 70 and the glass member 52 is 500 μm which is longer than the length of the wires, and thus interference between the wires sticking out from the sensor chip 7 and the glass member 52 can be prevented. In the first embodiment, a spacer member (not shown) having a thickness greater than 500 μm (specifically, sum total of the spacing t₀ and spacing t₇ shown in FIG. 2) is arranged between the sensor substrate 8 and the glass member 52. By this spacer member, the 500 μm spacing to is secured precisely. The spacing t₇ is the distance from a surface of the sensor substrate 8 on the +Z-axis side to a surface of the light receiving pixel unit 70 on the +Z-axis side.

The plurality of microlenses 14 are arranged on the +Z-axis side relative to the plurality of openings 32. The optical axis of the microlens 14 is indicated by the reference character 40 (see FIGS. 2 and 3). The microlenses 14 are apart from the plurality of openings 31 via the glass member 51 in the optical axis direction (i.e., the Z-axis direction). The microlens 14 is a condensing lens that condenses the reflected light reflected by the document 6. The microlens 14 is a convex lens, for example.

The plurality of microlenses 14 are arranged at positions corresponding respectively to the plurality of light receiving pixel units 70. In the first embodiment, as viewed in the Z-axis direction, the plurality of microlenses 14 respectively overlap with the plurality of light receiving pixel units 70. The plurality of microlenses 14 are arrayed in two lines. The microlenses 14 in each line are arrayed in the X-axis direction. In the first embodiment, the plurality of microlenses 14 are arrayed in a zigzag pattern. The microlenses 14 arrayed in the zigzag pattern constitute a microlens array 60.

The microlens array 60 is produced by a method such as nanoimprinting or injection molding, for example. In such cases, a mold used for manufacturing the microlens array 60 has concave parts corresponding to the shape of the microlens array 60. By manufacturing the microlens array 60 by means of nanoimprinting as above, the shape accuracy of the microlens array 60 can be increased. Further, by nanoimprinting, the microlens array 60 can be formed directly on the second light blocking member 12.

In the first embodiment, the diameter of the microlens 14 is set at a predetermined size in a range of some micrometers to some millimeters. The curvature radius of the surface of the microlens 14 is approximately 1.0 mm, for example. Further, the plurality of microlenses 14 are arranged at positions corresponding respectively to the plurality of openings 31. Specifically, on an XY plane, the central position of each microlens 14 overlaps with the central position of an opening 31. Accordingly, the optical axis 40 of each microlens 14 extends in the Z-axis direction orthogonal to the XY plane.

### Configuration of Illuminating Optical Unit

FIG. 6 is a diagram schematically showing the configuration of the illuminating optical unit 2 shown in FIG. 1 and the illuminating light 25 emitted from the illuminating optical unit 2. As shown in FIGS. 2 and 6, the illuminating optical unit 2 includes a light source 20 and a light guide member 21. The light source 20 is arranged at an end face 21a of the light guide member 21. The light source 20 emits light 20a to the inside of the light guide member 21. The light source 20 is a semiconductor light source, for example. The semiconductor light source is an LED (Light Emitting Diode) or the like, for example.

As shown in FIG. 6, the light guide member 21 points the light 20a emitted from the light source 20 towards the document 6. The light guide member 21 is, for example, a member in a cylindrical shape formed with a light-permeable resin material. The light 20a emitted from the light source 20 propagates while repeatedly undergoing total reflection inside the light guide member 21. A scattering region 22 is formed in a partial region of an internal side surface of the light guide member 21. The light 20a hitting the scattering region 22 is scattered and turns into scattered light. Then, part of the scattered light serves as the illuminating light 25 that illuminates the document 6.

The illuminating light 25 applied to the document 6 shown in FIG. 2 is reflected by the document 6 and turns into the reflected light. The reflected light successively passes through the microlenses 14, the openings 32, the glass member 51, the openings 31, the glass member 52 and the openings 33, and enters the light receiving pixel units 70.

### image Formation by Microlens 14

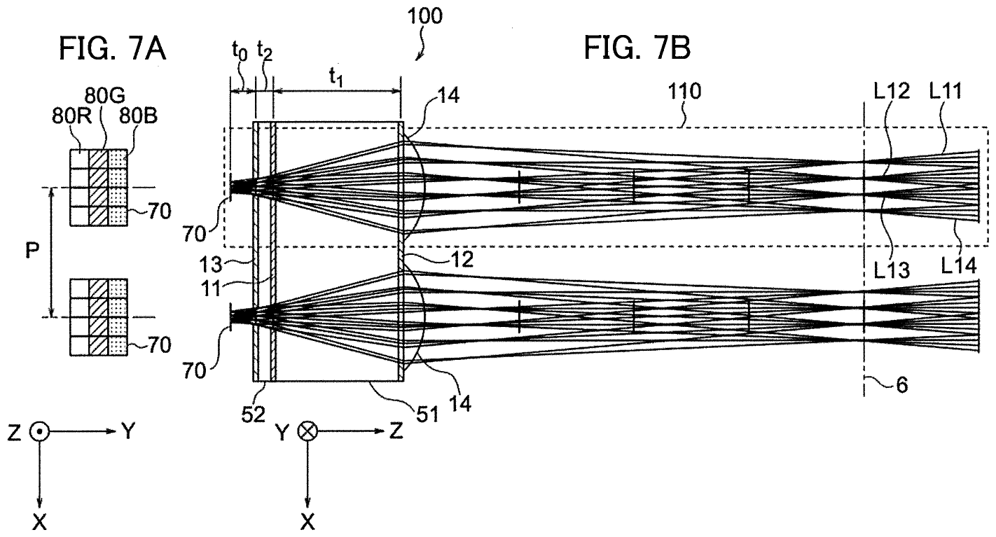

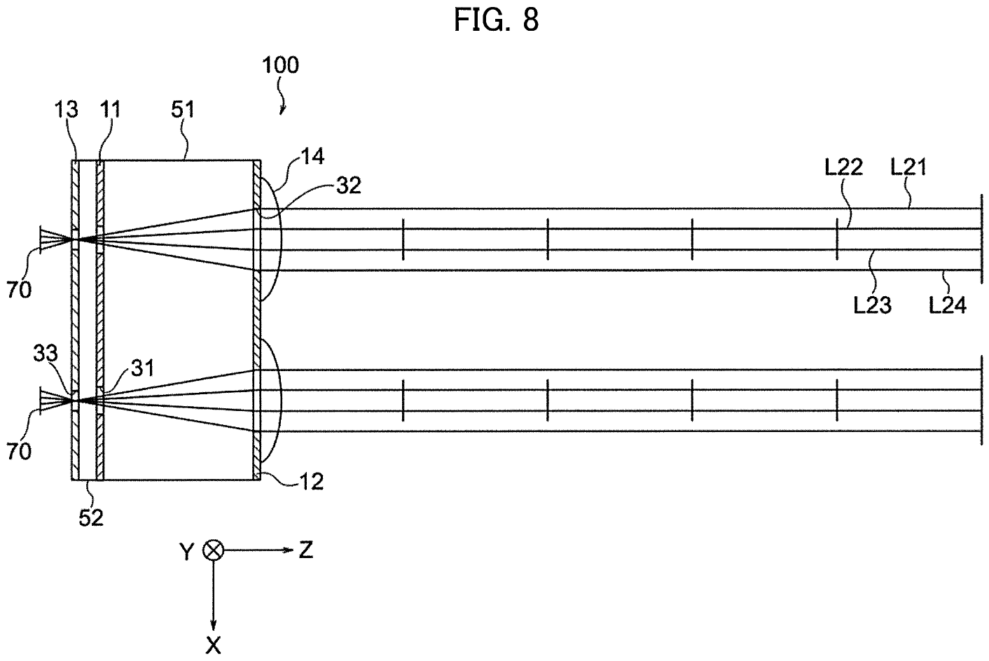

Next, image formation by the microlens 14 will be described below by using FIGS. 7A and 7B. FIG. 7A is a plan view showing two light receiving pixel units 70 situated in the same line. FIG. 7B is a diagram showing image forming rays L11 to L14 in the reflected light entering each of the two light receiving pixel units 70 shown in FIG. 7A. Each image forming ray L11-L14 is an inverse ray heading in an inverse direction (i.e., the +Z-axis direction) from the central position of each of four second light receiving pixels 80G among the plurality of light receiving pixels 80 included in one light receiving pixel unit 70.

As shown in FIG. 7B, the microlens 14 forms an image of the document 6 situated on an object surface, on the light receiving pixel unit 70 situated on an image formation surface. In the first embodiment, a reduction ratio (referred to also as an “image transfer magnification ratio”) between the object surface and the image formation surface is ¼. As mentioned earlier, the interval P₁ (see FIG. 5A) between the central positions of light receiving pixels 80 adjoining in the X-axis direction is 10 μm. Further, in one light receiving pixel unit 70, the number of light receiving pixels 80 arrayed in the X-axis direction is four. Thus, let r represent an X-axis direction resolution of the image reading device 100 on the document 6 (in other words, a pitch in a conjugate image of the light receiving pixels 80 on the document 6), the resolution r is 40 μm.

In the first embodiment, an imaging unit 110 as a unit optical system is formed by one microlens 14, one opening 32, one opening 31, one opening 33 and one light receiving pixel unit 70. Here, as mentioned earlier, a plurality of light receiving pixel units 70 are formed on one sensor chip 7. Therefore, the positional accuracy among the plurality of light receiving pixel units 70 can be increased. Thus, variation in the position of the optical axis 40 of the microlens 14 is small between imaging units 110 adjoining in the X-axis direction.

Further, in the example shown in FIG. 7B, the opening 31 is an aperture surface for the microlens 14, and thus a numerical aperture on each of an imaging side and an object side is determined by the opening 31. If an opening width of the opening 31 is large, the numerical aperture on the object side becomes large, and thus a light reception amount of the reflected light reflected by the document 6 can be increased. However, in this case, the depth of field decreases. Further, when it is attempted to increase the numerical aperture on the object side by widening the opening width of the opening 31 in a compound-eye optical system in which a plurality of imaging units 110 are arrayed, there as a danger or acquiring an image affected by stray light due to a ray entering one of two adjoining imaging units 110 and then entering the light receiving pixel unit 70 of the other imaging unit 110. However, in the first embodiment, an image not affected by stray light is acquired by satisfying conditions 1 and 2 which will be described later.

In the first embodiment, the microlens 14 is object side telecentric. By this, the depth of field can be increased. In order to realize the object side telecentricity, the opening 33 as an aperture surface for the microlens 14 is arranged at the position of a rear-side focal point of the microlens 14.

FIG. 8 is a diagram showing principal rays L21 to L24 in the image reading device 100 according to the first embodiment. The principal rays L21 to L24 are rays respectively included in the image forming rays L11 to L14 shown in FIG. 7B and passing through the center of the opening 33. In the first embodiment, centers of the openings 31, 32 and 33 or with each other as viewed in the Z-axis direction, and thus an optical axis of the imaging unit 110 (here, straight line connecting the center of the aperture surface and the center of the microlens 14) is in parallel with the Z-axis direction. Further, the principal rays L21 to L24 of each microlens 14 are in parallel with the optical axis direction. Thus, in the image forming rays L11 to L14 reflected by the object (specifically, the document 6) and focused in the imaging optical unit 1, the principal rays L21 to L24 are parallel to each other in the Z-axis direction. Accordingly, even when the position of the document 6 in the Z-axis direction changes, X-axis direction intervals of the principal rays L21 to L24 on the object side do not change and the reduction ratio does not change.

Next, the image formation by the microlens 14 will be described below by using specific numerical values. In FIG. 7B, the distance between the light receiving pixel unit 70 and the third light blocking member 13 is represented as t₀, and the distance between the third light blocking member 13 and the first light blocking member 11 (i.e., the thickness of the glass member 52) is represented as t₂. Further, the distance between the first light blocking member 11 and the second light blocking member 12 (i.e., the thickness of the glass member 51) is represented as t₁, and the refractive index of each glass member 51, 52 is represented as n.

Furthermore, let f represent the focal distance of the microlens 14 and R represent the curvature radius of the microlens 14, f=1.78 mm and R=0.95 mm. In order to realize the object side telecentricity, the focal distance f needs to satisfy the following expression (1):

f=(t₁+t₂)/n (1)

In an example in the first embodiment, t₁=300 μm, t₂=2400 μm and n=1.52, and thus the value of the focal distance f obtained by substituting these values into the expression (1) is 1.78 mm. Therefore, the microlens 14 is object side telecentric. Since the depth of field is increased by this feature, the distance between the Z-axis direction position of the document 6 as an image formation position on the object side and the Z-axis direction position of the microlens 14 can be increased. In other words, the plurality of microlenses 14, the first light blocking member 11 and the plurality of light receiving pixel units 70 are arranged so that reflected light reflected by the document 6 and passing through a microlens 14 and the opening 31 corresponding to the microlens 14 enters the plurality of light receiving pixels 80 included in the light receiving pixel unit 70 corresponding to the opening 31.

In the first embodiment, the Z-axis direction position of the document 6 is separate from the Z-axis direction position of the microlens 14 to the +Z-axis side by approximately 8 mm (see FIG. 1). Namely, in the first embodiment, an object distance is approximately 8 mm. Therefore, the illuminating optical unit 2 and the glass top plate 3 can be arranged between the document 6 and the microlenses 14.

Here, the depth of field is determined by the microlens 14's numerical aperture on the object side. Further, the numerical aperture on the object side is determined by the opening width of the opening 31 and the spacing t₀. Namely, a desired depth of field can be obtained by changing the opening width of the opening 31. While she definition of the depth of field changes depending, on a permissible range of contrast of the image, the depth of field is approximately 8 mm in the first embodiment, and thus a sufficiently great depth of field can be obtained for the image reading device 100 employed for a copy machine. While the opening 33 is the aperture surface for the microlens 14 in the first embodiment, the opening 31 may also be the aperture surface. In this case, the object side telecentricity can be realized if the opening 31 is arranged at the position of the rear-side focal point of the microlens 14.

### Number of Light Receiving Pixels for Preventing Loss of Image Information

In order to prevent loss of image information between imaging units 110 adjoining in the X-axis direction, the number N of light receiving pixels 80 arrayed in the X-axis direction and included in one light receiving pixel unit 70 needs to be set greater than or equal to a predetermined number. In the plurality of light receiving pixel units 70 arrayed in the 2-line zigzag pattern as shown in FIG. 4 explained earlier, the pitch P₀ between the two adjoining light receiving pixel units 71 and 72 is P/2.

Here, since the plurality of microlenses 14 are arranged at positions corresponding respectively to the plurality of light receiving pixel units 70, the interval between the central positions of two microlenses 14 adjoining in the X-axis direction (namely, the interval of the optical axes 40) is also P/2. When the following expression (2) is satisfied, the pitch P₀ is equal to an X-axis direction width of the microlens 14 as a visual field range of one microlens 14. Thus, the loss of image information can be prevented between the two microlenses 14. Further, when the expression (2) is satisfied, overlap of the visual fields of ad joining microlenses 14 can also be prevented.

P₀=P/2=N·r (2).

In an example in the first embodiment, P=320 μm, N=4 and r=40 μm, and thus the above expression (2) is satisfied.

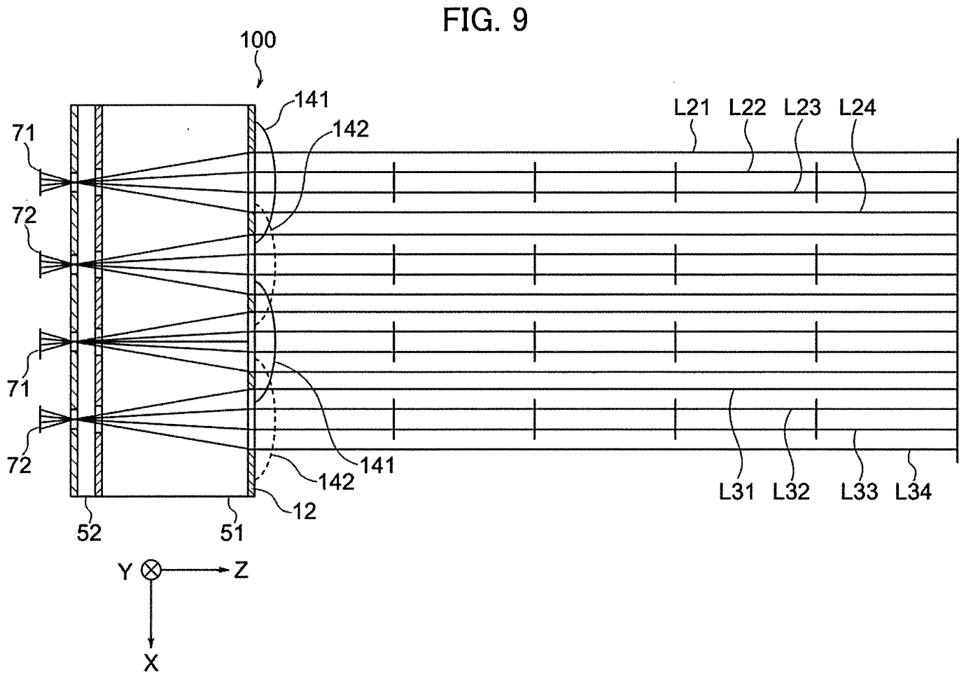

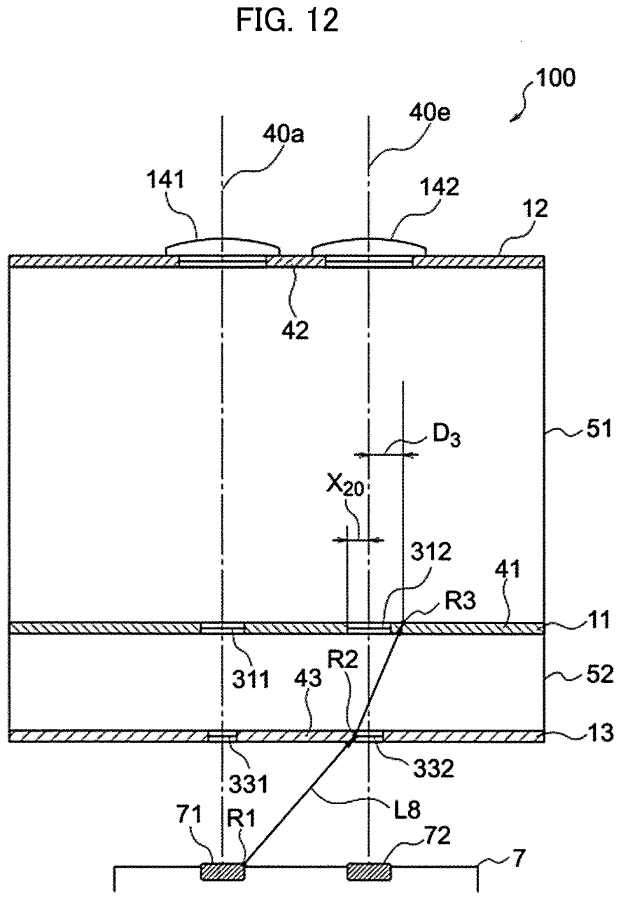

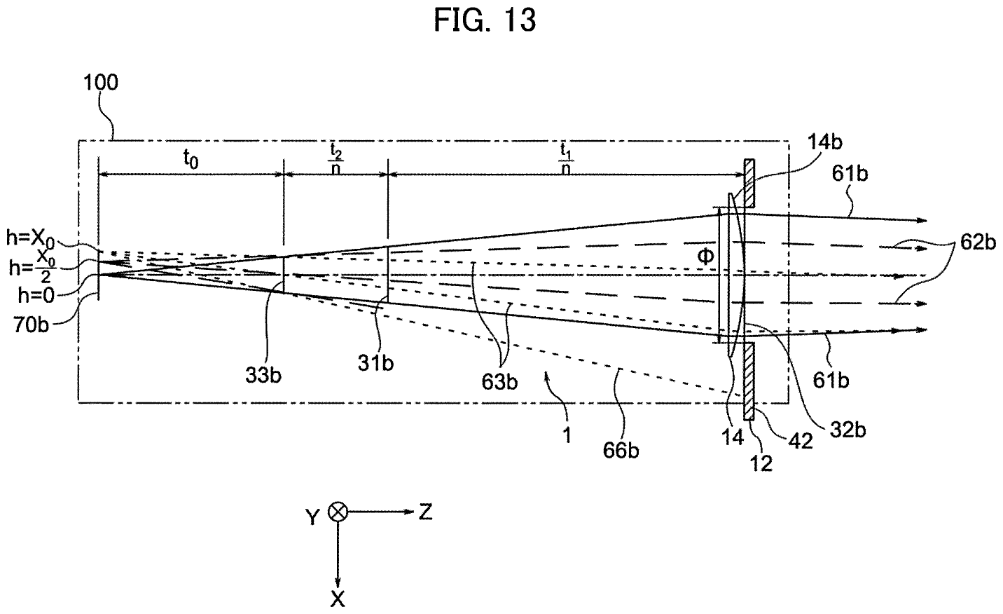

FIG. 9 is a diagram showing the principal rays L21 to L24 entering a light receiving pixel unit 71 situated in the first line 70m shown in FIG. 4 and principal rays L31 to L34 entering a light receiving pixel unit 72 situated in the second line 70n shown in FIG. 4 in the image reading device 100 according to the first embodiment. In FIG. 9 and FIG. 12 which will be explained. later, a microlens 14 overlapping with a light receiving pixel unit 71 is referred to as a microlens 141, and a microlens 14 overlapping with a light receiving pixel unit 72 is referred to as a microlens 142.

An X-axis direction distance between the microlens 141 and the microlens 142 is 160 μm. Therefore, in a space on the object side, the four principal rays L21 to L24 are arranged at 40 μm intervals in the X-axis direction. Further, the four principal rays L21 to L24 are also arranged at 40 μm intervals in the X-axis direction. Namely, spatial resolution in the X-axis direction on the object side is 40 μm, and the spatial resolution is 40 μm and does not change between imaging units 110 adjoining in the X-axis direction. As above, in the first embodiment, all the principal rays L21 to L24 and L31 to L34 are parallel to the Z-axis direction. Thus, the reduction ratio does not change irrespective of the position of the document 6 in the Z-axis direction. Accordingly, between imaging units 110 belonging to different lines, the loss of image information can be prevented and the overlap of the visual fields can also be prevented.

### Conditions for Acquiring Image not Affected by Stray Light

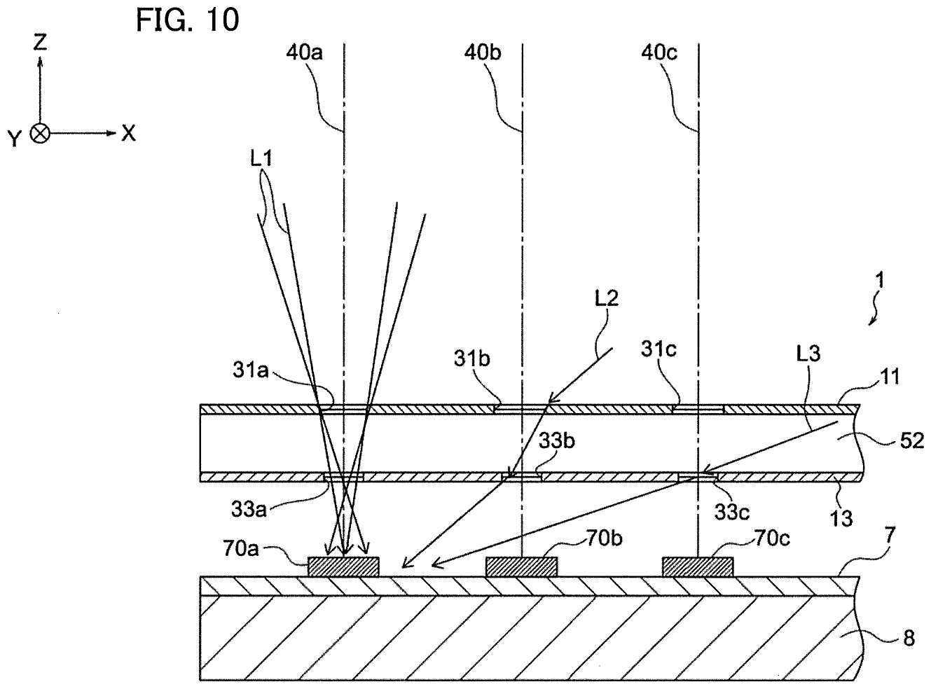

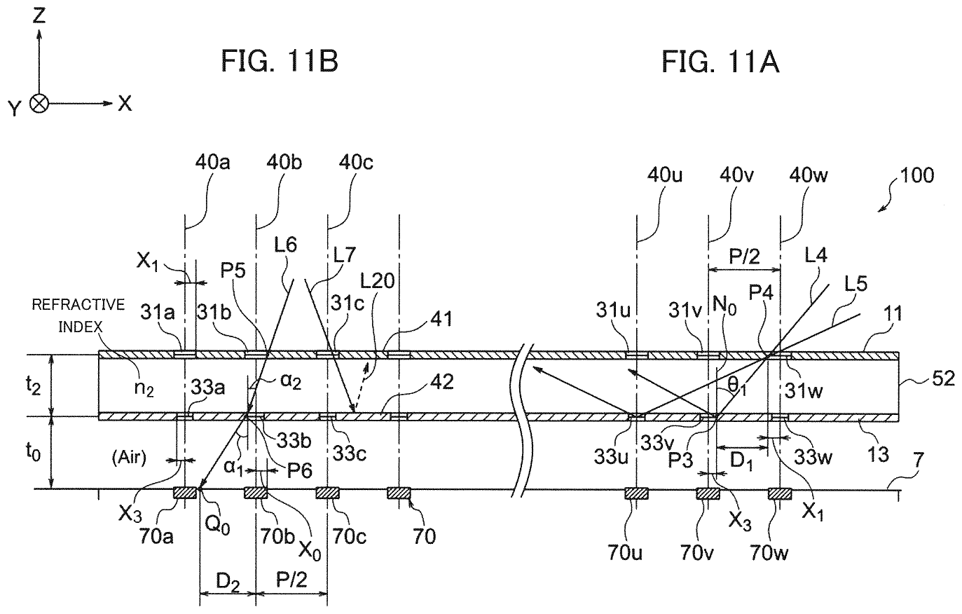

Next, conditions for the image reading device 100 for acquiring an image not affected by stray light will be described below by using FIGS. 10, 11A and 11B. FIG. 10 is a diagram showing a part of the configuration of the image reading device 100 shown in FIG. 3 and the reflected light passing through the opening 31 and the opening 33. Referring to FIG. 10, the conditions for acquiring an image not affected by stray light traveling in the X-axis direction will be described below. In FIG. 10, a plurality of light receiving pixel units 70 arrayed in the X-axis direction are represented also as light receiving pixel units 70a, 70b and 70c. Similarly, a plurality of openings 31 are represented also as openings 31a, 31b and 31c, and a plurality of openings 33 are represented also as openings 33a, 33b and 33c. Further, in the following description, a straight line connecting the center of an opening 32, the center of an opening 31 and a light receiving pixel unit 70 is referred to as an optical axis 40a, 40b, 40c.

In FIG. 10, reflected light from the document 6 (see FIG. 1) passing through an opening 31 and an opening 33 is indicated as rays L1, L2 and L3. The ray L1 passes through the opening 31a and the opening 33a and then enters the light receiving pixel unit 70a.

FIGS. 11A and 11B are diagrams for explaining conditions for the reflected light after passing through an opening 31 and an opening 33 to enter a light receiving pixel unit 70 in the image reading device 100. In FIGS. 11A and 11B, the thickness of the glass member 52 is represented as t₂, the refractive index of the glass member 52 is represented as n₂, and the distance between the glass member 52 and the light receiving pixel unit 70 is represented as t₀. When the following conditions 1 and 2 are both satisfied, only the reflected light after passing through the opening 31 and the opening 33 situated on the same optical axis enters the light receiving pixel unit 70 situated on the optical axis.

### Condition 1

Among rays passing through an opening 31 and an opening 33 having optical axes different from each other, there exists no ray that enters a light receiving pixel unit 70.

### Condition 2

A ray that passed through an opening 31 and an opening 33 having the same optical axis does not arrive at a light receiving pixel unit 70 other than the light receiving pixel unit 70 on the same optical axis.

For the condition 1, a sufficient condition is that the smallest incidence angle θ₁ of a ray at an opening 31, among the incidence angles of the rays passing through an opening 31 and an opening 33 having optical axes different from each other, satisfies the following expression (3):

n₂·sin θ₁>1 (3).

Next, the condition of the expression (3) will be expressed below by using parameters of the thickness and the opening width of the glass member 52. Opening half widths as ½ widths of the opening widths at the opening 31 and the opening 33 are respectively represented as X₁ and X₃. Further, a ½ width of the width of the light receiving pixel unit 70 in the X-axis direction is represented as X₀. A distance D₁ in the X-axis direction between a −X-axis direction end of an opening 33w and a +X-axis direction end of an opening 33v is obtained by the following expression (4):

D₁=(P/2)−X₁−X₂ (4).

As is clear from FIG. 11A, a relationship of the following expression (5) is satisfied in regard to the incidence angle θ₁ of a ray L4:

tan θ₁=D₁/t₂((P/2)−X₁−X₂)/t₂ (5)

From the expression (3) and the expression (5), the following expression (6) is derived in regard to the thickness t₂ of the glass member 52 satisfying the aforementioned condition 1:

t₂<\sqrt{n₂²−1}·((P/2)−X₁−X₂) (6).

Namely, the ray L4 satisfies an internal total reflection condition if the thickness t₂ of the glass member 52 is less than the value on the right side of the expression (6). In this case, the aforementioned condition 1 is satisfied.

Next, the aforementioned condition 2 will be explained below by using FIG. 11B. The following explanation will be given by using one light receiving pixel unit 70b among the plurality of light receiving pixel units 70 and light receiving pixel units 70a and 70c respectively adjoining the light receiving pixel unit 70b on both sides in the X-axis direction, for example. The aforementioned condition 2 is satisfied when a ray L6 passing through a point P5 in the opening 31b overlapping with the light receiving pixel unit 70b and a point P6 in the opening 33b overlapping with the light receiving pixel unit 70b arrives at a region between the light receiving pixel unit 70a and the light receiving pixel unit 70c and enters neither of the light receiving pixel unit 70a and the light receiving pixel unit 70c. The region between the light receiving pixel unit 70a and the light receiving pixel unit 70c is a region sandwiched between the right end of the light receiving pixel unit 70a and the left end of the light receiving pixel unit 70c shown in FIG. 11B.

The ray L6 shown in FIG. 11B is a ray that passes through the opening 31b and the opening 33b overlapping with the opening 31b. In FIG. 11B, the ray L6 passes through an end part of the opening 31b closest to the opening 31c and thereafter passes through an end part of the opening 33b closest to the opening 33a. The ray L6 that passed through the opening 33b arrives at a point Q₀. Here, the point Q₀ represents a point in a region between the light receiving pixel unit 70a and the light receiving pixel unit 70b at which the ray L6 arrived. In FIG. 11B, the point Q₀ represents a point that is the farthest from the light receiving pixel unit 70b in the −X-axis direction, that is, a point that is the closest to the receiving pixel unit 70a. As above, when the ray L6 arrives at the point Q₀ as a point on the light receiving pixel unit 70d's side relative to an end of the light receiving pixel unit 70a closest to the light receiving pixel unit 70b, the ray that passed through the opening 31b and the opening 33b does not arrive at an opening (e.g., the light receiving pixel unit 70a or the light receiving pixel unit 70c) other than the light receiving pixel unit 70b.

Here, let α₁ represent the emission angle of the ray L6 and α₂ represent the incidence angle of the ray L6, the incidence angle α₂ is obtained by using the following expression (7):

tan α₂=(X₁+X₂)/t₂ (7).

Further, according to the Snell's law, the relationship between the emission angle α₁ and the incidence angle α₂ is represented by the following expression (8):

n₂·sin α₂=sin α₁ (8).

Furthermore, the distance D₂ from the optical axis 40b to the point Q₀ is obtained by using the following expression (9):

D₂=X₁+t₀·tan α₁ (9).

Here, the condition that the point Q₀ is situated on the light receiving pixel unit 70b's side relative to the end of the light receiving pixel unit 70a in the +X-axis direction is represented by the following expression (10):

P/2−X₀>X₁+t₀·tan α₁ (10).

From the expressions (7) to (10), the following expression (11) is derived in regard to the thickness t₂ of the glass member 52 satisfying the aforementioned condition 2:

$$\\ \begin{matrix}{t}_{2} > ( {X}_{1} + {X}_{2} ) \cdot \sqrt{{n}_{2}^{{}^{} 2} - 1 + \frac{{n}_{2}^{{}^{} 2} \cdot {t}_{0}^{{}^{} 2}}{{( ( P / 2 ) - {X}_{1} - {X}_{0} )}^{2}}} . & ( 11 )\end{matrix}$$

Namely, the aforementioned condition 2 is satisfied when the thickness t₂ of the glass member 52 is greater than the value or the right side of the expression (11).

In an example in the first embodiment, X₁=20 μm, X₂=30 μm, X₀=20 μm, t₀=500 μm, P/2=160 μm, and n₂=1.52. With these values substituted into the right sides of the expression (6) and the expression (11), the right sides of the expressions respectively take on values of 126 μm and 322 μm. Thus, t₂=300 μm satisfies both of the expression (6) and the expression (11).

Next, a relationship between the array of the plurality of light receiving pixel units 70 and the aforementioned conditions 1 and 2 will be explained below by using FIG. 4. The plurality of light receiving pixel units 70 are arrayed in a plurality of rows and a plurality of columns. Further, in FIG. 4, the plurality of light receiving pixel units 70 are arrayed in a zigzag pattern. Suppose that resolution equal to that of the image reading device 100 according to the first embodiment is obtained in an image reading device in which the plurality of light receiving pixel units are arrayed in one line, an array pitch of the light receiving pixel units in the main scanning direction (i.e., the X-axis direction) needs to be set at a half value (i.e., 160 μm) of the array pitch of the light receiving pixel units 70 in the first embodiment. In other words, the array pitch of the light receiving pixel units 70 arrayed in the same line can be set long in the image reading device 100 according to the first embodiment.

In contrast, in the image reading device in which the plurality of light receiving pixel units are arrayed in one line, it is difficult to obtain the thickness t₂ satisfying both of the aforementioned expressions (6) and (11) while maintaining the opening half widths of the openings at great values. Even in the case where the plurality of light receiving pixel units are arrayed in one line, there exists the thickness t₂ as a parameter satisfying both of the expression (6) and the expression (11). Therefore, the above explanations (e.g., the explanations regarding the aforementioned conditions 1 and 2), excluding the explanations regarding the configuration in which the plurality of light receiving pixel units 70 are arrayed in two lines, are applied also to the case where the plurality of light receiving pixel units are arrayed in one line.

Next, a description will be given of conditions for a ray after passing through an opening 31 and an opening 33 arranged at positions overlapping with a light receiving pixel unit 70 belonging to one line included in the two lines of light receiving pixel units 70 for not entering a light receiving pixel unit 70 belonging to the other line in the image reading device 100.

FIG. 12 is a cross-sectional view of the image reading device 100 shown in FIG. 1 taken along the line A12-A12. In FIG. 12, the opening 31, 33 overlapping with a light receiving pixel unit 71 is represented as an opening 311, 331, and the opening 31, 33 overlapping with a light receiving pixel unit 72 is represented as an opening 312, 332. Further, the optical axis of the microlens 141 is represented by a reference character 40a, and the optical axis of the microlens 142 is represented by a reference character 40e. A point R1 is an end of the light receiving pixel unit 71 closest to the light receiving pixel unit 72. A point R2 is an end of the opening 332 closest to the opening 331. A point R3 is a point situated on an outer side relative to an end of the opening 312 farthest from the opening 311.

Further, in FIG. 12, an inverse ray L8 as a virtual ray heading from the light receiving pixel unit 71 towards the opening 312 is used. The inverse ray L8 is a ray that travels from the point R1, passes through the point R2, and arrives at the point R3. The distance between the point R3 and the optical axis 40e is represented as D₃, and a ½ length of the length of a diagonal line of the opening 312 in a square shape is represented as X₂₀.

The following description will be given of the conditions for a ray after passing through the opening 312 and the opening 332 for not entering the light receiving pixel unit 71. If the inverse ray L8 arrives at the first light blocking part 41 or a third light blocking part 43, the ray after passing through the opening 312 and the opening 332 does not enter the light receiving pixel unit 71. Referring to FIG. 12, the description will be given by taking an example of a case where the inverse ray L8 arrives at the first light blocking part 41.

If the distance D₃ is greater than the length X₂₀, the inverse ray L8 arrives at the first light blocking part 41. Accordingly, the ray after passing through the opening 312 and the opening 332 does not enter the light receiving pixel unit 71. Even supposing that the distance D₃ is less than the length X₂₀ and the inverse ray L8 passes through the opening 312, if she interval q shown in FIG. 4 is long, the inverse ray L8 arrives at the second light blocking part 42. Thus, even when the distance D₃ is less than the length X₂₀, the ray after passing through the opening 312 and the opening 332 does not enter the light receiving pixel unit 71 since the interval q is long and the image reading device 100 includes the second light blocking member 12.

### Different Configuration of Second Light Blocking Member 12

Next, a different configuration of the second light blocking member 12 will be described below by using FIG. 13. FIG. 13 is a diagram showing inverse rays 61b, 62b, 63b and 66b heading in the +Z-axis direction from the light receiving pixel unit 70b in the image reading device 100. In FIG. 13, the glass member 51 having the refractive index n and the thickness is shown while being replaced with a glass member 51 having a refractive index 1 and a thickness t₁/n, that is, the glass member replaced with air. Further, the glass member 52 having the refractive index n and the thickness t₂ is shown as a glass member 52 having a refractive index 1 and a thickness t₂/n. The microlens 14 is arranged while securing spacing from the opening 32b of the second light blocking member 12 by the distance t₂/n.

The inverse rays 61b, 62b, 63b and 66b are inverse rays heading in the +Z-axis direction from an object surface defined as a light receiving surface of the light receiving pixel unit 70b. The inverse say 61b is an inverse ray heading in the +Z-axis direction from a point on the object surface where an object height h=0. The inverse ray 62b is an inverse ray heading in the +Z-axis direction from a point on the object surface where the object height h=X₀/2. The inverse ray 63b is an inverse ray heading in the +Z-axis direction from a point on the object surface where the object height h=X₀. The inverse ray 66b, which is an inverse ray heading in the +Z-axis direction from the point where the image height h=X₀ similarly to the inverse ray 63b, is blocked by the second light blocking member 12.

The opening width (diameter Φ in FIG. 13) of the opening 32 of the second light blocking member 12 is smaller than an external diameter of the microlens 14. Therefore, the inverse ray 66b shown in FIG. 13 arrives at the second light blocking part 42. Since the inverse ray 66b is an inverse ray heading in the +Z-axis direction from an end of the light receiving pixel unit 70b in the −X-axis direction, all of the rays entering the light receiving pixel unit 70b pass through the opening 32b. Namely, when scattered and reflected light from the document 6 arrives at a position outside the microlens 14 in the X-axis direction, the scattered and reflected light is blocked by the second light blocking part 42 and thus does not arrive at the light receiving pixel unit 70b. Accordingly, deterioration in the contrast of the image or occurrence of a ghost image is prevented in the image reading device 100. Therefore, the image reading device 100 is capable of reading out an image having excellent image quality.

### Relationship Between Scan Width and Number of Sensor Chips

Next, a relationship between a scan width (hereinafter referred so also as a “scan length”) of the image reading device 100 and the number of sensor chips 7 will be described below. When manufacturing an image reading device 100 whose scan length is 200 mm, a configuration in which the imaging element unit is provided with one sensor chip that is 200 mm long in the X-axis direction can be considered to be unrealistic. Therefore, the imaging element unit 10 implements the image reading device 100 whose scan length is 200 mm by including a plurality of sensor chips 7 arrayed in the X-axis direction as shown in FIG. 4. A concrete number of the sensor chips 7 will be described below.

The aforementioned pitch P of the light receiving pixel units 70 is represented by the following expression (12) by using the number N of light receiving pixels 80 arrayed in the X-axis direction in one light receiving pixel unit 70 and the resolution r:

P=2·N·r (12).

Since N=4 and r=40 μm in an example of the first embodiment, substituting these values into the expression (12) results in P=320 μm.

Further, in the first embodiment, one sensor chip 7 includes 64 light receiving pixel units 70. Thus, let M represent the number of light receiving pixels 80 arrayed in the X-axis direction in one sensor chip 7, the number M is 64×4=256.

Assuming that an imaging range in the X-axis direction that can be captured by one sensor chip 7 is A, the imaging range A is represented by the following expression (13) by using the aforementioned number M and the resolution r:

A=M·r (13).

By substituting M=256 and r=40 μm into the expression (13), A=10.24 mm is derived. Thus, in order to implement the image reading device 100 whose scan length is 200 mm, it is sufficient if the imaging element unit 10 includes 20 sensor chips 7.

Here, for arraying a plurality of sensor chips 7 on the sensor substrate 8, it is necessary to prevent a defect of a pixel in a boundary region of adjoining sensor chips 7. In order to prevent the defect, it is necessary, for example, to set the interval between the light receiving pixel unit 70z situated at the +X-axis direction end of the sensor chip 7a and the light receiving pixel unit 70a situated at the −X-axis direction end of the sensor chip 7b shown in FIG. 4 at P/2 (160 μm in the first embodiment).

As shown in FIGS. 5A and 5B, the distance from the point C₁ on the light receiving pixel unit 70z to an end 70e of she light receiving pixel unit 70z in the +X-axis direction and the distance from the point C₂ on the light receiving pixel unit 70a to an end 70f of the light receiving pixel unit 70a in the +X-axis direction are respectively referred to as distances P₂. Further, let Xg represent spacing between the light receiving pixel unit 70z and the light receiving pixel unit 70a shown in FIG. 4, the spacing Xg is represented by the following expression (14):

Xg=P/2−2·P₂ (14).

Since P/2=160 μm and P₂=20 μm in the first embodiment, substituting these values into the expression (14) results in Xg=120 μm.

One sensor chip 7 is formed by being cut out from a silicon wafer by a dicing apparatus. Therefore, in consideration of a cutting margin, a cutting error or the like, a margin is necessary when cutting the silicon wafer. In the first embodiment, the distance between the end 70e of the light receiving pixel unit 70z in the +X-axis direction and the end 7e of the sensor chip 7a in the +X-axis direction and the distance between the end 70f of the light receiving pixel unit 70a in the −X-axis direction and an end of the sensor chip 7a in the −X-axis direction are set at values smaller than 60 μm as ½ of the aforementioned spacing Xg. Accordingly, the defect of a pixel can be prevented in the boundary region of adjoining sensor chips 7. Since the image transfer magnification ratio of the microlens 14 is ¼ and is smaller than 1, the margin necessary when cutting the silicon wafer can be provided.

### Relationship Between Assembly Error and Acquired Image

As mentioned earlier, in the first embodiment, a plurality of openings are formed in the same glass member and a plurality of microlenses 14 are also formed on the same glass member 51. With this feature, the positional accuracy among a plurality of openings or a plurality of microlenses 14 situated on the same plane can be made excellent. In the first embodiment, the first light blocking member 11 including the plurality of openings 31, the second light blocking member 12 including the plurality of openings 32, and the microlens array 60 including the plurality of microlenses 14 are formed on the glass member 51. Further, the third light blocking member 13 including the plurality of openings 33 is formed on the glass member 52.

Here, it is possible to consider increasing positioning accuracy of the central positions of the microlenses 14 and the central positions of the openings 31, 32 and 33 and accuracy of the positioning of the central positions of the openings 31, 32 and 33 differing in the Z-axis direction position by forming alignment marks for the alignment on the glass members 51 and 52. However, the alignment of members differing in the Z-axis direction position tends to have a greater error compared to the alignment of members situated on the same plane. Further, when a process of sticking the glass member 51 and the glass member 52 together by using alignment marks is necessary, it is difficult to reduce the error to 0.

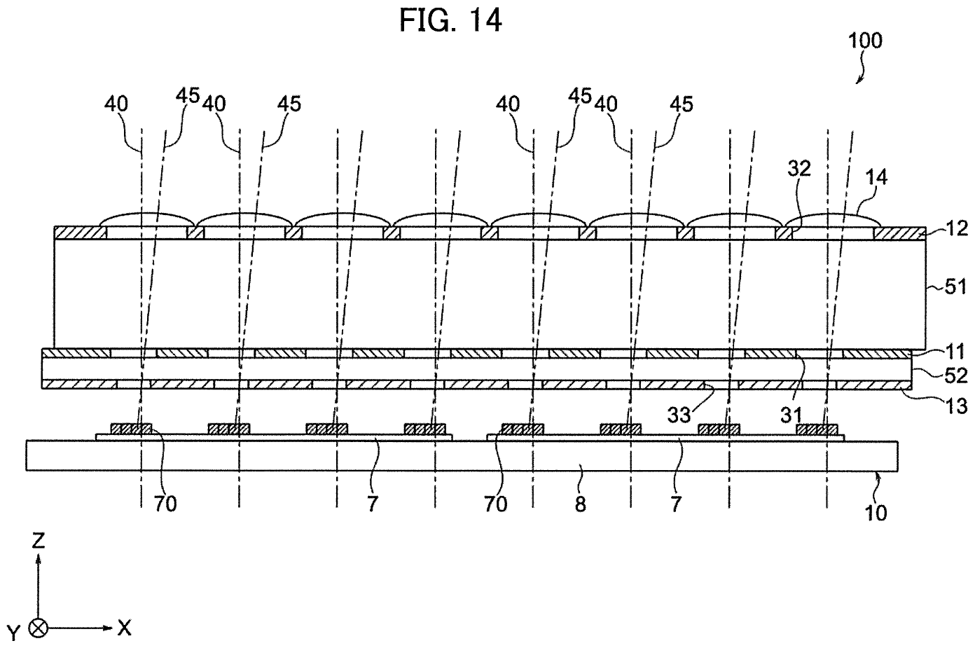

Influence of displacement (misalignment) on image processing when the displacement occurs in the process of sticking the glass member 51 and the glass member 52 together will be described below by using FIG. 14. FIG. 14 is a diagram showing an inclination of the optical axis of the microlens when displacement of a first glass member and a second glass member occurs in the image reading device according to the first embodiment. In FIG. 14, the central position of each of the glass members 51 and 52 is deviated to the +X-axis side with respect to the central position of the imaging element unit 10. Further, the glass members 51 and 52 are arranged in a state in which the central position of the glass member 51 in the X-axis direction is deviated to the +X-axis side with respect to the central position of the glass member 52 in the X-axis direction.

In FIG. 14, the optical axis of the microlens 14 when such displacement occurs is represented bye a reference character 45. The optical axis 45 of the microlens 14 is inclined to the +X-axis side with respect to the optical axis 40. Therefore, an intersection point (e.g., point C₃ shown in FIG. 5C) where the optical axis 45 and the light receiving pixel unit 70 intersect with each other is deviated in the −X-axis direction. In this case, it is necessary to perform alignment work of adjusting the central position of the imaging element unit 10 in the X-axis direction to coincides with the central position of each glass member 51, 52 in the X-axis direction so that the intersection point coincides with the central position of the light receiving pixel unit 70 in the X-axis direction.

However, in the first embodiment, the optical axes 45 adjoining in the X-axis direction are parallel to each other even though the glass members 51 and 52 are deviated in the X-axis direction with respect to the imaging element unit 10. With this feature, the overlap or separation of the visual fields of the microlenses 14 between adjoining imaging units 110 (see FIG. 7B) is prevented. Accordingly, the image reading device 100 is capable of reading out an image having excellent image quality with no overlap or loss of image information even when the displacement of the glass member 51 or 52 with respect to the imaging element unit 10 occurs.

Suppose that the plurality of microlenses 14 (or the plurality of openings) are not formed integrally on the same plane, variation occurs in the central positions of the microlens 14 and the openings 31, 32 and 33 in one imaging unit 110. In this case, the adjoining optical axes 45 do not become parallel to each other as in the first embodiment. Therefore, the overlap or separation of the visual fields of the microlenses 14 occurs between adjoining imaging units 110, and thus the overlap or loss of image information occurs. Accordingly, in the image reading device 100 including a plurality of imaging units 110, the plurality of microlenses 14 formed integrally on the same plane and the plurality of openings formed integrally on the same plane are a configuration necessary for reading out an image having excellent image quality.

### Mitigation of Variation in Mounting of Sensor Chips

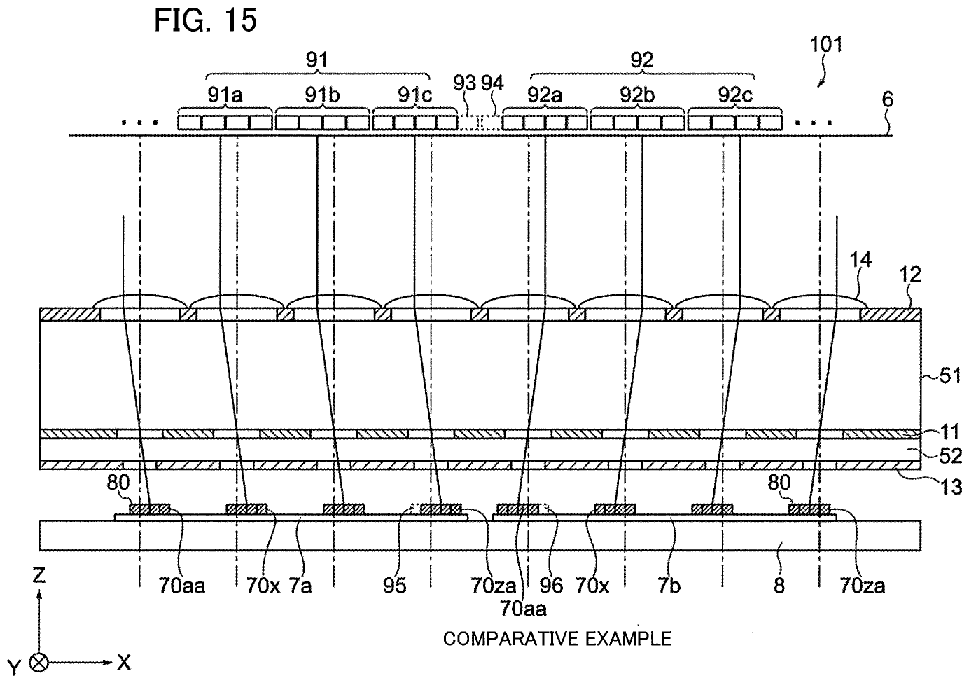

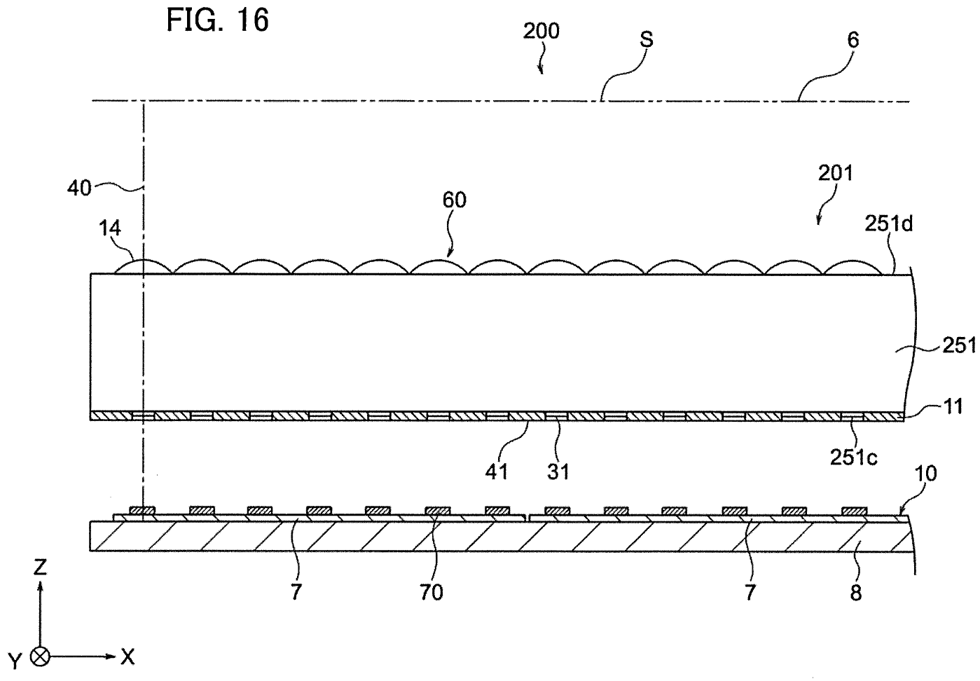

Next, a method for mitigating variation in the mounting of the sensor chips 7 will be described below in contrast with a comparative example by using FIG. 15. As shown in FIG. 4 explained earlier, in the first embodiment, a plurality of sensor chips 7 are mounted on the sensor substrate 8. Accordingly, there are cases where the displacement occurs between adjoining sensor chips 7.

FIG. 15 is a diagram showing X-axis direction positions of the visual fields of the microlenses 14 when variation in the mounting of the sensor chips 7a and 7b occurs in an image reading device 101 according to the comparative example. The image reading device 101 differs from the image reading device 100 according to the first embodiment in that the number of light receiving pixels 80 arrayed in the X-axis direction in each of light receiving pixel units 70aa and 70za respectively arranged at positions closest to X-axis direction ends of the sensor chip 7a or 7b is four.

In FIG. 15, a visual field focused on the sensor chip 7a is represented by a reference character 91, and a visual field focused on the sensor chip 7b is represented by a reference character 92. Further, in FIG. 15, regions arrayed in the X-axis direction by division of the visual field 91 are represented by reference characters 91a, 91b, 91c, and regions arrayed in the X-axis direction by division of the visual field 92 are represented by reference characters 92a, 92b, 92c.

In the example shown in FIG. 15, the sensor chip 7a is deviated in the +X-axis direction by 10 μm corresponding to one pixel of the light receiving pixel 80. The sensor chip 7b is deviated in the −X-axis direction by 10 μm. In this case, the visual field 91 is deviated in the −X-axis direction by 40 μm corresponding to one pixel and that causes a visual field loss region 93. Further, the visual field 92 is deviated in the +X-axis direction by 40 μm and that causes a visual field loss region 94. Therefore, a visual field loss of 80 μm corresponding to two pixels occurs between the visual field 91 and the visual field 92. In this case, restoration of the image cannot be executed since image information in the visual field loss part is not acquired. The visual field loss region 93 forms an image in a region 95 adjoining the light receiving pixel unit 70za on the −X-axis side. The visual field loss region 94 forms an image in a region 96 adjoining the light receiving pixel unit 70aa on the +X-axis side.

In the first embodiment, as shown in FIGS. 5A to 5C, the number of light receiving pixels 80 arrayed in the X-axis direction in each of the light receiving pixel units 70z and 70a is greater than the number of light receiving pixels 80 arrayed in the X-axis direction in the light receiving pixel unit 70b by 1. In other words, in the first embodiment, light receiving pixels 80 are arranged in the visual field loss regions 93 and 94. With this feature, the occurrence of the visual field loss can be prevented even when variation in the mounting of the sensor chips 7a and 7b occurs. When the distance between the sensor chip 7a and the sensor chip 7b increases or the Y-axis direction position of the sensor chip 7a and the Y-axis direction position of the sensor chip 7b deviate from each other, the displacement can be corrected by means of image processing. The method of the correction will be described later.

### Restoration of Image

Next, a method of restoring the image of the document 6 by image processing executed by the image processing device 9 will be described below. The image processing device 9 converts an analog image signal outputted from the sensor chips 7 into digital image data and executes image processing described below. In the first embodiment, the plurality of light receiving pixel units 70 are arrayed in a zigzag pattern as shown in FIG. 4, and thus the central position of the light receiving pixel unit 71 belonging to the first line 70m and the central position of the light receiving pixel unit 72 belonging to the second line 70n are deviated from each other in the Y-axis direction by the distance q. Therefore, when the document 6 is scanned in the Y-axis direction, the image of the document 6 has to be restored to an image with no displacement. Specifically, the image processing device 9 after acquiring image information from the light receiving pixel units 71 in the first line 70m and image information from the light receiving pixel units 72 in the second line 70n executes a process of shifting the image information in the Y-axis direction by a certain number of pixels corresponding to the distance q (hereinafter referred to as an “image combination process”).

In FIG. 4, the light receiving pixel units 70 in the second line 70n are arrayed to be deviated in the X-axis direction with respect to the light receiving pixel units 70 in the first line 70m by the pitch P/2 as ½ of the pitch P. In order to set the resolution in the X-axis direction and the resolution in the Y-axis direction at the same value, it is sufficient if the image processing device 9 acquires signals outputted from the light receiving pixel units 70 at a time interval for conveying the document 6 in the Y-axis direction by the resolution r on the document surface. While the distance q representing the displacement amount of the image information is desired to be an integral multiple of the resolution r on the document surface, the distance q is not limited to an integral multiple of the resolution r. It is also possible for the image processing device 9 to estimate luminance values at subpixel positions by using a pixel complementing process and synthesize image information by using the estimated luminance values. Further, it is also possible for the image processing device 9 to shift the timing for the light receiving pixel units 71 belonging to the first line 70m to obtain image information and the timing for the light receiving pixel units 72 belonging to the second line 70n to obtain image information from each other and combine the obtained pieces of image information together.

Here, a method for the image processing device 9 for correcting the overlap or deviation of visual fields 91 caused by the variation in the mounting of the sensor chips 7 will be described below. As described earlier, in each of the light receiving pixel units 70z and 70a respectively arranged at positions closest to X-axis direction ends of the sensor chip 7, one light receiving pixel 80 is additionally arranged in the X-axis direction. Therefore, then the mounting of a sensor chip 7 varies in the X-axis direction within the range of the one light receiving pixel 80, light receiving pixel loss on the document 6 does not occur.

When the sensor chip 7a has deviated in the −X-axis direction and the sensor chip 7b has deviated in the +X-axis direction in FIG. 15, a visual field 91z and the visual field 91a overlap with each other. In this case, it is desirable if a process of removing overlapping light receiving pixels is executed when the image processing device 9 combines the image information obtained by the sensor chip 7a and the image information obtained by the sensor chip 7b together. Further, when a subpixel overlap smaller than one pixel unit occurs, it is desirable to restore the image by executing an image complementing process at the subpixel position so that no contradiction occurs between the overlapping visual fields 91.

Furthermore, when the mounting of a sensor chip 7 varies in the Y-axis direction, the interval between reading positions on the document 6 between sensor chips 7 adjoining in the X-axis direction deviates from the distance q in the Y-axis direction. However, this deviation is corrected based on a shift amount as the distance for which the image processing device 9 shifts the image information in the Y-axis direction. Moreover, also for a subpixel deviation in the Y-axis direction, it is desirable to execute the image complementing process at the subpixel position.

### Effect of First Embodiment

According to the first embodiment described above, the image reading device 100 includes a plurality of light receiving pixel units 70 arrayed regularly. Further, the light receiving pixel unit 70 includes a plurality of light receiving pixels 80 arrayed in the main scanning direction. With this configuration, the resolution can be improved in the image reading device 100. Further, the occurrence of variation in the direction of the optical axis between adjoining imaging units 110 can be prevented.

According to the first embodiment, the microlens 14 is object side telecentric. Further, the plurality of microlenses 14, the first light blocking member 11 and the plurality of light receiving pixel units 70 are arranged so that reflected light reflected by the document 6 and passing through a microlens 14 and the opening 31 corresponding to the microlens 14 enters the plurality of light receiving pixels 80 included in the light receiving pixel unit 70 corresponding to the opening 31. Therefore, the visual field of the microlens 14 does not overlap with the visual field of adjoining another microlens 14, and no gap occurs. Since the depth of field is increased by this feature, the distance between the Z-axis direction position of the document 6 as the image formation position on the object side and the Z-axis direction position of the microlens 14 can be increased.

According to the first embodiment, the plurality of light receiving pixel units 70 are arrayed in a zigzag pattern and the plurality of openings 31 are arrayed in a zigzag pattern so as to correspond respectively to the plurality of light receiving pixel units 70. Further, the plurality of microlenses 14 are arrayed in a zigzag pattern so as to correspond respectively to the plurality of openings 31. The pitch P₀ between the light receiving pixel unit 71 and the light receiving pixel unit 72 belonging to different lines among the plurality of light receiving pixel units 70 satisfies the aforementioned expression (2). Accordingly, irrespective of the distance from the light receiving pixel unit 70 to the document 6, the visual field of the microlens 14 does not overlap with the visual field of adjoining another microlens 14, and no loss occurs. Thus, the depth of field can be increased in the image reading device 100.

According to the first embodiment, the image reading device 100 further includes the glass member 51 having the surface 51a, on which the first light blocking member 11 is provided, including the plurality of openings 31 and the surface 51c, on which the microlens array 60 is provided (i.e., the plurality of microlenses 14). With this configuration, the first light blocking member 11 and the microlens array 60 can be formed integrally on the same member. Further, the positional accuracy of the plurality of openings 31 and the plurality of microlenses 14 can be increased. Thus, the occurrence of the variation in the direction of the optical axis between adjoining imaging units 110 can be prevented. In other words, the occurrence of the visual field overlap or loss can be prevented between adjoining microlenses 14.

According to the first embodiment, the plurality of light receiving pixel units 70 included in one sensor chip 7 include the light receiving pixel units 70z and 70a respectively arranged at positions closest to the +X-axis direction end 7e and the −X-axis direction end 7f of the sensor chip 7 and the light receiving pixel units 70x other than the light receiving pixel units 70z and 70a. The number of light receiving pixels 80 arrayed in the X-axis direction in the light receiving pixel unit 70z, 70a is greater than the number of light receiving pixels 80 in the light receiving pixel unit 70x. With this feature, the occurrence of the visual field loss can be prevented even when the variation in the mounting of the sensor chips 7 occurs.

According to the first embodiment, since the thickness t₂ of the glass member 52 satisfies the aforementioned expression (6), reflected light after passing through an opening 32 and an opening 31 situated on the same optical axis as a light receiving pixel unit 70 enters the light receiving pixel unit 70, and thus an. image not affected by stray light can be acquired.

According to the first embodiment, since the thickness t₂ of the glass member 52 satisfies the aforementioned expression (11), the depth of field can be increased. further,

According to the first embodiment, the image reading device 100 includes The second light blocking member 12 provided on the surface of the glass member 51 on the +Z-axis side and including a plurality of openings 32 corresponding respectively to the plurality of microlenses 14. The opening width Φ of each opening 32 included in the plurality of openings 32 is smaller than the external diameter of the micro lens 14. With this feature, reflected light not passing through the microlenses 14, included in the reflected light reflected by the document 6, is blocked by the second light blocking member 12. Thus, the image reading device 100 is capable of reading out an image having excellent image quality.

According to the first embodiment, the plurality of light receiving pixel units 70 include a plurality of light receiving pixel units 71 in the first line 70m and a plurality of light receiving pixel units 72 in the second line 70n arrayed at different positions in the auxiliary scanning direction. Each light receiving pixel unit 72 included in the plurality of light receiving pixel units 72 is arranged between two light receiving pixel units 71 adjoining in the main scanning direction. Namely, the plurality of light receiving pixel units 70 are arrayed in a zigzag pattern. Accordingly, the pitch P can be increased compared to a configuration in which a plurality of light receiving pixel units are arrayed in one line, and thus the image reading device 100 is capable of acquiring an image not affected by stray light. Further, the luminance of the image can be increased.

### Second Embodiment

FIG. 16 is a cross-sectional view schematically showing a main configuration of an image reading device 200 according to a second embodiment. In FIG. 16, each component identical or corresponding to a component shown in FIG. 3 is assigned the same reference character as in FIG. 3. The image reading device 200 according to the second embodiment differs from the image reading device 100 according to the first embodiment in not including the second light blocking member 12, the third light blocking member 13 and the glass member 52. Except for this feature, the image reading device 200 according to the second embodiment is the same as the image reading device 100 according to the first embodiment.

As shown in FIG. 16, the image reading device 200 includes an imaging optical unit 201. The imaging optical unit 201 includes the imaging element unit 10, the first light blocking member 11 including the plurality of openings 31, the microlens array 60 including the plurality of microlenses 14, and a glass member 251. The first light blocking member 11 is provided on a surface 251c of the glass member 251 on the −Z-axis side, and the microlens array 60 is provided on a surface 251d of the glass member 251 on the +Z-axis side.

### Effect of Second Embodiment

According to the second embodiment described above, the image reading device 200 does not include the second light blocking member 12 (see FIG. 3) differently from the image reading device 100 according to the first embodiment, and thus the process of forming the second light blocking member 12 on the glass member 251 becomes unnecessary. Accordingly, a manufacturing process of the image reading device 200 can be simplified.

Further, according to the second embodiment, the image reading device 200 does not include the class member 52 (see FIG. 3) provided with the third light blocking member 13 differently from the image reading device 100 according to the first embodiment, and thus the process of sticking the glass member 251 and the glass member 52 together becomes unnecessary. Accordingly, the manufacturing process of the image reading device 200 can be simplified further.

### Modification of Second Embodiment

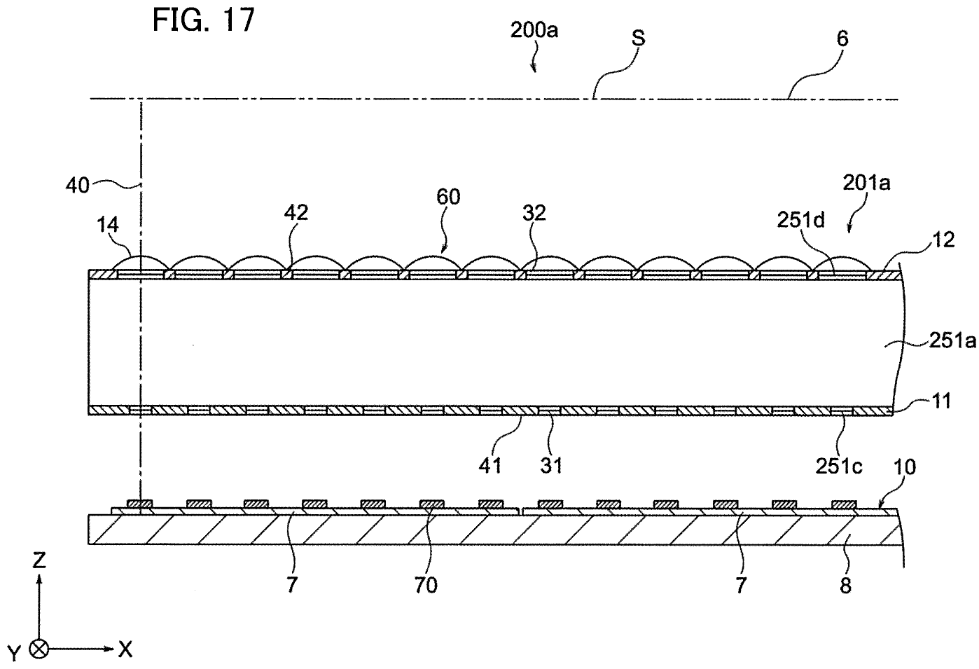

FIG. 17 is a cross-sectional view showing a main configuration of an image reading device 200a according to the second embodiment. In FIG. 17, each component identical or corresponding to a component shown in FIG. 16 is assigned the same reference character as in FIG. 16. The image reading device 200a according to the modification of the second embodiment differs from the image reading device 200 according to the second embodiment in further including the second light blocking member 12. Except for this feature, the image reading device 200a according to the modification of the second embodiment is the same as the image reading device 200 according to the second embodiment.

As shown in FIG. 17, the image reading device 200a includes an imaging optical unit 201a. The imaging optical unit 201a includes the imaging element unit 10, the first light blocking member 11 including the plurality of openings 31, the second light blocking member 12 including the plurality of openings 32, the microlens array 60 including the plurality of microlenses 14, and a glass member 251a. The second light blocking member 12 is provided on a surface 251d of the glass member 251a on the +Z-axis side. The second light blocking member 12 is arranged between the surface 251d of the glass member 251a on the +Z-axis side and the microlens array 60.

### Effect of Modification of Second Embodiment

According to the modification of the second embodiment described above, the image reading device 200a includes the second light blocking member 12 arranged between the surface 251d of the glass member 251a on the +Z-axis side and the microlens array 60. With this configuration, when scattered and reflected light from the document 6 arrives at a position outside the microlens 14 the X-axis direction, the scattered and reflected light is blocked by the second light blocking part 42 of the second light blocking member 12 and thus does not arrive at the light receiving pixel unit 70. Accordingly, the image reading device 200a is capable of reading out an image not affected by stray light.

### Third Embodiment

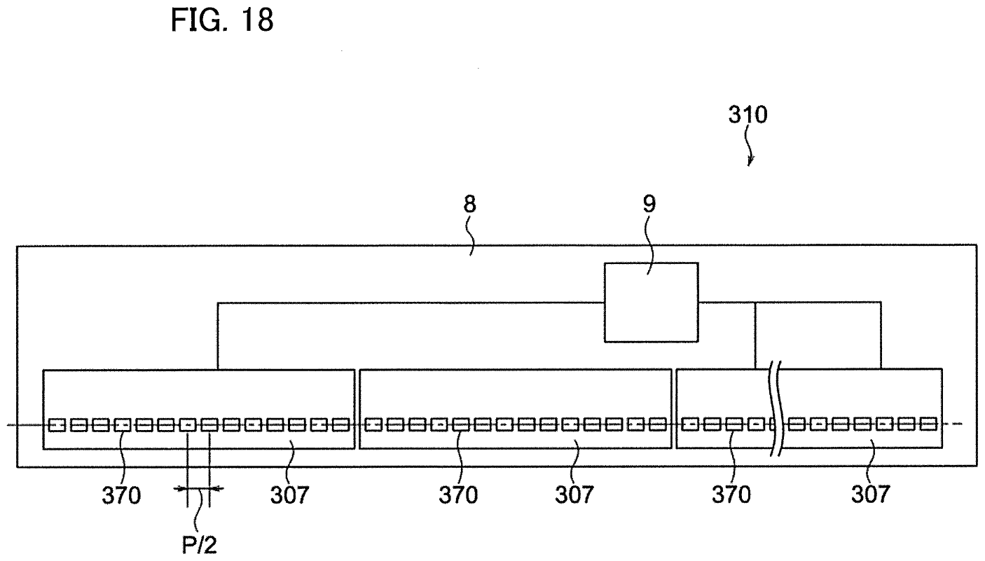

FIG. 18 is a plan view showing the configuration of an imaging element unit 310 of an image reading device according to a third embodiment. In FIG. 18, each component identical or corresponding to a component shown in FIG. 4 is assigned the same reference character as in FIG. 4. The imaging element unit 310 according to the third embodiment differs from the imaging element unit 10 of the image reading device 100 according to the first embodiment in that a plurality of light receiving pixel units 370 are arrayed in one line. Except for this feature, the image reading device according to the third embodiment is the same as the image reading device 100 according to the first embodiment. Thus, FIG. 3 is referred to in the following description.

The imaging element unit 310 includes a plurality of sensor chips 307, the sensor substrate 8, and the image processing device 9. Each sensor chip 307 includes a plurality of light receiving pixel units 370. In the third embodiment, the plurality of light receiving pixel units 370 are arrayed in the X-axis direction in one line. Accordingly, the image processing in the image processing device 9 can be simplified in comparison with the configuration in which the plurality of light receiving pixel units 70 (see FIG. 4) are arrayed in a zigzag pattern. Specifically, in the third embodiment, the aforementioned image combination process executed in the first embodiment becomes unnecessary.

While illustration is left out, the plurality of microlenses 14, the plurality of openings 32, the plurality of openings 31 and the plurality of openings 33 are arranged at positions corresponding respectively to the plurality of light receiving pixel units 370. Namely, the plurality of microlenses 14, the plurality of openings 32, the plurality of openings and the plurality of openings 33 are respectively arrayed in the X-axis direction in one line. An imaging unit as a unit optical system is formed by one light receiving pixel unit 370 and one microlens 14, one opening 32, one opening 31 and one opening 33 situated on the same optical axis as the light receiving pixel unit 370. in the case where the plurality of light receiving pixel units 370 are arrayed in one line as above, there is a danger of occurrence of stray light since the interval between the imaging units adjoining in the X-axis direction becomes narrower. However, by reducing the opening width of the opening 31, the image reading device according to the third embodiment is capable of acquiring an image not affected by stray light.

### Effect of Third Embodiment

According to the third embodiment described above, the plurality of light receiving pixel units 370 are arrayed in one line. Accordingly, in the third embodiment, the image combination process becomes unnecessary and thus the image processing in the image processing device 9 can be simplified in comparison with the configuration in which the plurality of light receiving pixel units 70 (see FIG. 4) are arrayed in a zigzag pattern.

### Fourth Embodiment

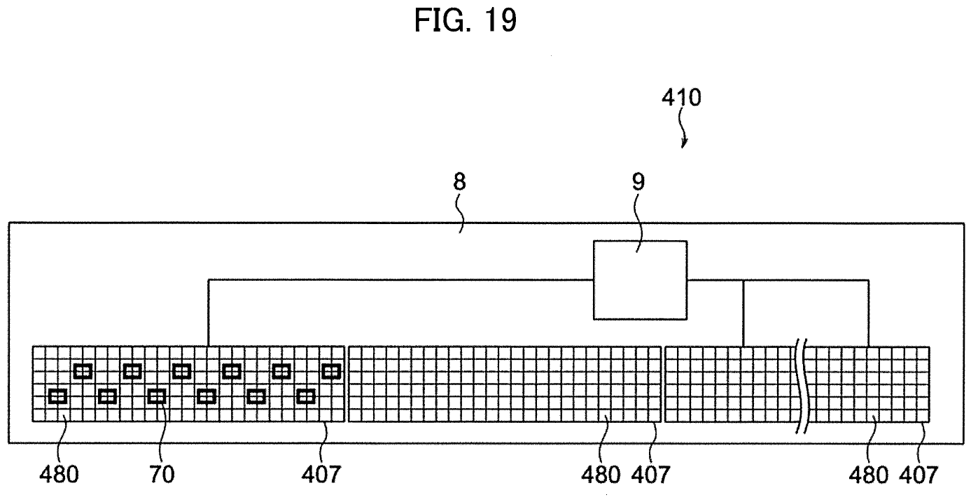

FIG. 19 is a cross-sectional view showing the configuration of an imaging element unit 410 of an image reading device according to a fourth embodiment. In FIG. 19, each component identical or corresponding to a component shown in FIG. 4 is assigned the same reference character as in FIG. 4. The image reading device according to the fourth embodiment differs from the image reading device 100 according to the first embodiment in the configuration of a sensor chip 407. Except for this feature, the image reading device according to the fourth embodiment is the same as the image reading device 100 according to the first embodiment.

As shown in FIG. 19, the imaging element unit 410 includes the sensor chips 407 as the light receiving parts, the sensor substrate 8 and the image processing device 9. Each sensor chip 407 includes a plurality of light receiving pixels 480 arrayed like a two-dimensional matrix. In other words, in the fourth embodiment, the light receiving pixels 480 adjoining in the X-axis direction are in contact with each other, and the light receiving pixels 480 adjoining in the Y-axis direction are in contact with each other. In general, the sensor chip includes a plurality of light receiving pixels arrayed like the two-dimensional matrix shown in FIG. 19.

To the image processing device 9, an image signal outputted from a plurality of light receiving pixels 480, among the aforementioned plurality of light receiving pixels 480, overlapping with the regions of the light receiving pixel units 70 shown in FIG. 4 is outputted.

### Effect of Fourth Embodiment

According to the fourth embodiment described above, the sensor-chip 407 includes a plurality of light receiving pixels 480 arrayed like a two-dimensional matrix. With this configuration, in contrast with the sensor chip 7 shown in FIG. 4, it is unnecessary to manufacture the special sensor chip 7 including a plurality of light receiving pixel units 70 arrayed in a zigzag pattern. Accordingly, the cost for the image reading device according to the fourth embodiment can be reduced.

### Fifth Embodiment

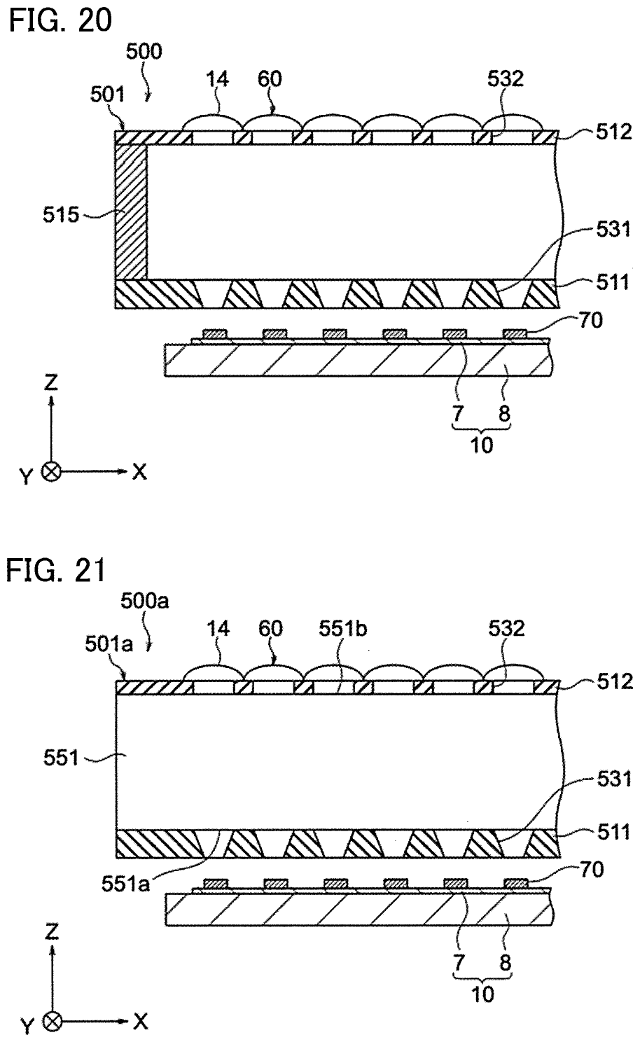

FIG. 20 is a cross-sectional view schematically showing a main configuration of an image reading device 500 according to a fifth embodiment. In FIG. 20, each component identical or corresponding to a component shown in FIG. 3 is assigned the same reference character as in FIG. 3. The image reading device 500 according to the fifth embodiment differs from the image reading device 100 according to the first embodiment in the configuration of an imaging optical unit 501. Except for this feature, the image reading device 500 according to the fifth embodiment is the same as the image reading device 100 according to the first embodiment.

As shown in FIG. 20, the image reading device 500 includes the imaging optical unit 501. The imaging optical unit 501 includes the imaging element unit 10, a first light blocking member 511, a second light blocking member 512, the microlens array 60 including the plurality of microlenses 14, and a spacer member 515.

The first light blocking member 511 includes a plurality of openings 531 as the plurality of first openings corresponding respectively to the plurality of light receiving pixel units 70. The thickness of the first light blocking member 511 is greater than the thickness of the first light blocking member 11 shown in FIG. 3. Further, in the example shown in FIG. 20, the opening width of the opening 531 becomes narrower as it goes from the +Z-axis side towards the −Z-axis side.

The second light blocking member 512 includes a plurality of openings 532 as the plurality of second openings corresponding respectively to the plurality of microlenses 14. The thickness of the second light blocking member 512 is greater than the thickness of the second light blocking member 12 shown in FIG. 3.

Each of the first light blocking member 511 and the second light blocking member 512 is formed from a metal plate, for example. The first light blocking member 511 and the second light blocking member 512 are formed by, for example, electroforming with which high processing accuracy can be obtained.

The microlens array 60 is formed on a surface of the second light blocking member 512 on the +Z-axis side. As mentioned above, in the fifth embodiment, the thickness of the second light blocking member 512 is greater than the thickness of the second light blocking member 12 in the first embodiment. Therefore, the plurality of openings 32 and the microlens array 60 can be formed even if the second light blocking member 512 is not supported by a glass member (e.g., the glass member 51 shown in FIG. 3).

The spacer member 515 connects the first light blocking member 511 and the second light blocking member 512 together. By this, spacing between the first light blocking member 511 and the second light blocking member 512 in the Z-axis direction is set at a predetermined size. As above, the image reading device 500 in the fifth embodiment does not include the glass member 51 shown in FIG. 3. The spacer member 515 is provided at ends of the first light blocking member 511 on both sides in the X-axis direction. The Y-axis direction position of the spacer member 515 on the −X-axis side and the Y-axis direction position of the spacer member (not shown) on the +Y-axis side may differ from each other. While illustration is left out, in the image reading device 500 as viewed on a Z-X cross section different from the Z-X cross section of FIG. 20, a spacer member may be arranged between the first light blocking member 511 and the second light blocking member 512.

### Effect of Fifth Embodiment

According to the fifth embodiment described above, each of the first light blocking member 511 and the second light blocking member 512 is formed from a metal plate. Therefore, each of the first light blocking member 511 and the second light blocking member 512 has a thickness in the Z-axis direction greater than or equal to a predetermined size. Thus, there exists no ray passing through an opening 532 and an opening 531 having optical axes different from each other. Accordingly, the image reading device 100 is capable of acquiring an image not affected by stray light.

Further, according to the fifth embodiment, the image reading device 500 includes the spacer members 515 connecting the first light blocking member 511 and the second light blocking member 512 together and the spacing between the first light blocking member 511 and the second light blocking member 512 is set at a predetermined size. With this configuration, the occurrence of the visual field overlap or loss can be prevented between adjoining imaging units, and thus the depth of field can be increased.

### First Modification of Fifth Embodiment

FIG. 21 is a cross-sectional view schematically showing a main configuration of an image reading device 500a according to a first modification of the fifth embodiment. In FIG. 21, each component identical or corresponding to a component shown in FIG. 20 is assigned the same reference character as in FIG. 20. The image reading device 500a according to the first modification of the fifth embodiment differs from the image reading device 500 according to the fifth embodiment in the configuration of an imaging optical unit 501a. Except for this feature, the image reading device 500a according to the first modification of the fifth embodiment is the same as the image reading device 500 according to the fifth embodiment.

As shown in FIG. 21, the image, reading device 500a includes the imaging optical unit 501a. The imaging optical unit 501a includes the imaging element unit 10, the first light blocking member 511 including the plurality of openings 531, the second light blocking member 512 including the plurality of openings 532, the microlens array 60 including the plurality of microlenses 14, and a glass member 551 as the first glass member.

The glass member 551 is arranged between the first light blocking member 511 and the second light blocking member 512. In this case, each of the first light blocking member 511 and the second light blocking member 512 can be manufactured by electroforming with which high processing accuracy can be obtained. The glass member 551 is stuck to the first light blocking member 511 and the second light blocking member 512.

### Effect of First Modification of Fifth Embodiment

According to the first modification of the fifth embodiment described above, the image reading device 500a includes the glass member 551 arranged between the first light blocking member 511 and the second light blocking member 512 and the spacing between the first light blocking member 511 and the second light blocking member 512 is set at a predetermined size. With this configuration, the occurrence of the visual field overlap or loss can be prevented between adjoining imaging units, and thus the depth of field can be increased.

### Second Modification of Fifth Embodiment

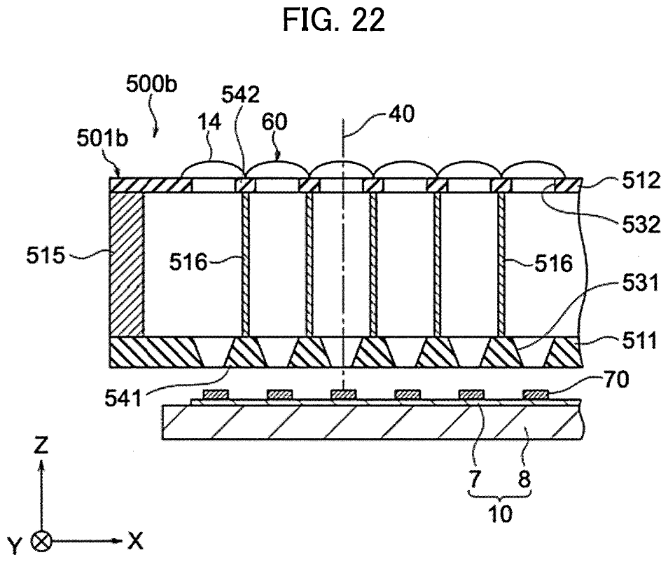

FIG. 22 is a cross-sectional view schematically showing a main configuration of an image reading device 500b according to a second modification of the fifth embodiment. In FIG. 22, each component identical or corresponding to a component shown in FIG. 20 is assigned the same reference character as in FIG. 20. The image reading device 500b according to the second modification of the fifth embodiment differs from the image reading device 500 according to the fifth embodiment in further including light blocking walls 516. Except for this feature, the image reading device 500b according to the second modification of the fifth embodiment is the same as the image reading device 500 according to the fifth embodiment.

As shown in FIG. 22, the image reading device 500b includes an imaging optical unit 501b. The imaging optical unit 501b includes the imaging element unit 10, the first light blocking member 511, the second light blocking member 512, the microlens array 60 including the plurality of microlenses 14, the spacer members 515, and a plurality of light blocking walls 516 as fourth light blocking members.

In the first light blocking member 511, a part excluding the plurality of openings 531 is a first light blocking part 541 that blocks the reflected light. In the second light blocking member 512, a part excluding the plurality of openings 532 is a second light blocking part 542 that blocks the reflected light.

Each light blocking wall 516 included in the plurality of light blocking walls 516 extends along the optical axis 40 of the microlens 14. The light blocking walls 516 connect the first light blocking part 541 and the second light blocking part 542 together. With this configuration, there can exist no ray passing through an opening 532 and an opening 531 having optical axes different from each other. Accordingly, the image reading device 500b is capable of acquiring an image not affected by stray light.

### Effect of Second Modification of Fifth Embodiment

According to the second modification of the fifth embodiment described above, the image reading device 500b includes the light blocking walls 516 connecting the first light blocking part 541 and the second light blocking part 542 together. With this configuration, there can exist no ray passing through an opening 532 and an opening 531 having optical axes different from each other. Accordingly, the image reading device 500b is capable of acquiring an image not affected by stray light.

### Sixth Embodiment

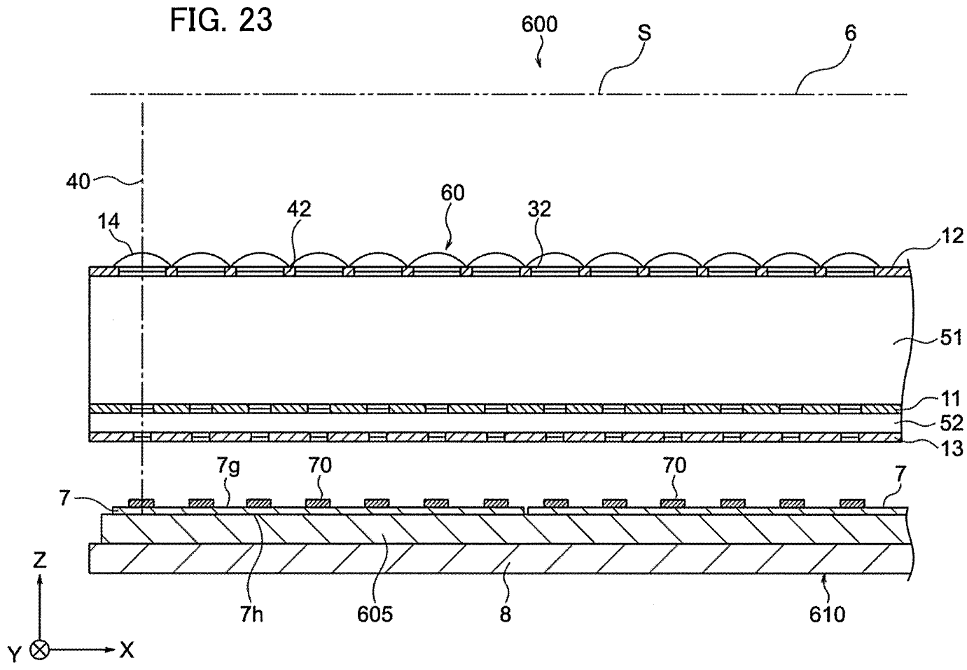

FIG. 23 is a cross-sectional view schematically showing a main configuration of an image reading device 600 according to a sixth embodiment. In FIG. 23, each component identical or corresponding to a component shown in FIG. 3 is assigned the same reference character as in FIG. 3. The image reading device 600 according to the sixth embodiment differs from the image reading device 100 according to the first embodiment in the configuration of an imaging element unit 610. Except for this feature, the image reading device 600 according to the sixth embodiment is the same as the image reading device 100 according to the first embodiment. Thus, FIG. 4 is referred to in the following description.

As shown in FIG. 23, the imaging element unit 610 includes the sensor chips 7 as first substrates, the sensor substrate 8, the image processing device 9 (see FIG. 4) and a sensor auxiliary substrate 605 as a second substrate.

The sensor auxiliary substrate 605 is bonded to surfaces 7h of the sensor chips 7 on the side opposite to surfaces 7g on which the plurality of light receiving pixel units 70 are provided. The sensor auxiliary substrate 605 is formed from glass material similarly to the glass members 51 and 52. The linear expansion coefficient of the sensor auxiliary substrate 605 is the same as the linear expansion coefficient of the glass members 51 and 52.

An electric circuit (not shown) is printed on the sensor auxiliary substrate 605. The electric circuit is electrically connected to the sensor chips 7 by means of wire bonding, for example. Further, the sensor auxiliary substrate 605 is electrically connected to an electric circuit provided on the sensor substrate 8 by means of wire bonding, for example. The image processing device 9 converts the analog image signal outputted from the sensor chips 7 into the digital image data.

In general, the linear expansion coefficient of glass epoxy resin as the material of the sensor substrate 8 is 3×10⁻⁵/° C., for example. On the other hand, the linear expansion coefficient of the glass members 51 and 52 is 7.0×10⁻⁶/° C., for example. Thus, there is a great difference between the linear expansion coefficient of the sensor substrate 8 and the linear expansion coefficient of the glass members 51 and 52. Therefore, in the image reading device 100 according to the first embodiment, displacement of the light receiving pixel unit 70 with respect to the optical axis 40 of the microlens 14 can occur upon the occurrence of a temperature change. Since this displacement causes a decrease in the light reception amount of each light receiving pixel unit 70, there is a danger of occurrence of a problem such as darkening of the image acquired by the image reading device 100 or impossibility of acquiring the image.

In the sixth embodiment, the sensor auxiliary substrate 605 as a glass member is bonded to the surfaces 7h of the sensor chips 7 on the side opposite to the surfaces 7g on which the plurality of light receiving pixel units 70 are provided. With this configuration, even when a temperature change occurs, the light receiving pixel unit 70 is situated on the optical axis of the microlens 14, and thus the decrease in the light reception amount of each light receiving pixel unit 70 can be prevented. Accordingly, the image reading device 600 is capable of acquiring an image having excellent image quality irrespective of the temperature change.

### Effect of Sixth Embodiment

According to the sixth embodiment described above, the image reading device 600 further includes the sensor auxiliary substrate 605 bonded to the surfaces 7h of the sensor chips 7 on the side opposite to the surfaces 7g on which the plurality of light receiving pixel units 70 are provided. With this configuration, even when a temperature change occurs, she light receiving pixel unit 70 is situated on the optical axis of the microlens 14, and thus the decrease in the light reception amount of each light receiving pixel unit 70 can be prevented. Accordingly, the image reading device 600 is capable of acquiring an image having excellent image quality irrespective of the temperature change.

### DESCRIPTION OF REFERENCE CHARACTERS

6: document, 7, 307, 407: sensor chip, 7e, 7f: end, 7g, 7h, 51a, 51b, 52a, 551a, 551b: surface, 11, 511: first light blocking member, 12, 512: second light blocking member, 13: third light blocking member, 14: microlens, 31, 32, 33, 531, 532: opening, 70, 70a, 70x, 70z, 71, 72: light receiving pixel unit, 70m: first line, 70n: second line, 80, 80R, 80G, 80B: light receiving pixel, 51, 251, 251a, 551: first glass member, 52: second glass member, 100, 200, 200a, 500, 500a, 500b, 600: image reading device, 515: spacer member, 516: light blocking wall, 605: sensor auxiliary substrate, N: number of pieces, P₀: distance, r: resolution, Φ: diameter.

1. An image reading device that optically reads an object as an image capture target, comprising:
a plurality of light receiving parts arrayed regularly;
a first light blocking member including a plurality of first openings arrayed corresponding respectively to the plurality of light receiving parts; and
a plurality of microlenses arrayed corresponding respectively to the plurality of first openings, the plurality of microlenses being formed integrally on a same plane, wherein
each light receiving part included in the plurality of light receiving parts includes a plurality of light receiving pixels arrayed in a first direction as a main scanning direction,
each microlens included in the plurality of microlenses is object side telecentric,
the plurality of microlenses are arrayed in a zigzag pattern,
the plurality of microlenses, the first light blocking member and the plurality of light receiving parts are arranged so that light reflected by the object and passing through the microlens and the first opening corresponding to the microlens enters the plurality of light receiving pixels included in the light receiving part corresponding to the first opening, and
an interval between central positions of two microlenses adjoining in the first direction among the plurality of microlenses is equal to a width of the microlens in the first direction as a visual field range of the microlens.

2. (canceled)

3. The image reading device according to claim 1, wherein let P₀ represent the interval between the central positions of the two adjoining microlenses, N represent a number of the plurality of light receiving pixels in the first direction included in each of the light receiving parts, and r represent a resolution of the image reading device in the first direction,
P₀=N·r
is satisfied.

4. The image reading device according to claim 1, further comprising a first glass member having a surface on which the first light blocking member is provided and a surface on which the plurality of microlenses are provided.

5. The image reading device according to claim 4, further comprising a second light blocking member provided on a surface of the first glass member on the object's side and including a plurality of second openings corresponding respectively to the plurality of microlenses,
wherein an opening width of each second opening included in the plurality of second openings in the first direction is smaller than an external diameter of the microlens.

6. The image reading device according to claim 1, further comprising a third light blocking member are provided on the plurality of light receiving parts' side relative to the first light blocking member and including a plurality of third openings corresponding respectively to the plurality of light receiving parts.

7. The image reading device according to claim 6, further comprising a second glass member having a surface on which the third light blocking member is provided.

8. An image reading device that optically reads an object as an image capture target, comprising:
a plurality of light receiving parts arrayed regularly;
a first light blocking member including a plurality of first openings arrayed corresponding respectively to the plurality of light receiving parts; and
a plurality of microlenses arrayed corresponding respectively to the plurality of first openings, wherein
each light receiving part included in the plurality of light receiving parts includes a plurality of light receiving pixels arrayed in a first direction as a main scanning direction,
each microlens included in the plurality of microlenses is object side telecentric, and
the plurality of microlenses, the first light blocking member and the plurality of light receiving parts are arranged so that light reflected by the object and passing through the microlens and the first opening corresponding to the microlens enters the plurality of light receiving pixels included in the light receiving part corresponding to the first opening,
the image reading device further comprising a first substrate on which the plurality of light receiving parts are arranged, wherein
the plurality of light receiving parts include:
first light receiving parts as the light receiving parts respectively arranged at positions closest to ends of the first substrate in the first direction;
second light receiving parts as the light receiving parts other than the first light receiving parts, and
a number of the plurality of light receiving pixels included in the first light receiving part is greater than a number of the plurality of light receiving pixels included in the second light receiving part.

9. The image reading device according to claim 8, further comprising:
a first glass member having a surface on which the first light blocking member is provided and a surface on which the plurality of microlenses are provided; and
a second substrate formed from glass material and bonded to a surface of the first substrate on a side opposite to a surface on which the plurality of light receiving parts are provided,
wherein a linear expansion coefficient of the second substrate is equal to a linear expansion coefficient of the first glass member.

10. The image reading device according to claim 1, wherein the plurality of light receiving parts are arrayed in one line.

11. The image reading device according to claim 1, wherein
the plurality of light receiving parts include a plurality of light receiving parts in a first line and a plurality of light receiving parts in a second line arrayed at different positions in a direction orthogonal to the first direction, and
each light receiving part included in the plurality of light receiving parts in the second line is arranged between two light receiving parts adjoining in the first direction among the plurality of light receiving parts in the first line.

12. The image reading device according to claim 1, wherein the plurality of light receiving pixels are arrayed like a matrix.

13. The image reading device according to claim 1, further comprising a second light blocking member provided between the first light blocking member and the plurality of microlenses and including a plurality of second openings corresponding respectively to the plurality of microlenses,
wherein each of the first light blocking member and the second light blocking member is formed from a metal plate.

14. The image reading device according to claim 13, further comprising a spacer member connecting the first light blocking member and the second light blocking member together.

15. The image reading device according to claim 13, further comprising a fourth light blocking member connecting a first light blocking part as a part of the first light blocking member excluding the plurality of first openings and a second light blocking part as a part of the second light blocking member excluding the plurality of second openings together.

16. The image reading device according to claim 13, further comprising a glass member having a surface in contact with the first light blocking member and a surface in contact with the second light blocking member.
